(19) United States
(12) Patent Application Publication
(10) Pub. No.: US 2025/0374509 A1
(43) Pub. Date: Dec. 4, 2025

(54) MULTI-PORT MEMORY DEVICE WITH ACTIVE REGION WIDTH OPTIMIZATION

(71) Applicant: Taiwan Semiconductor Manufacturing Company, Ltd., Hsin-Chu (TW)

(72) Inventors: Choh Fei YEAP, Hsinchu City (TW); Ping-Wei WANG, Hsin-Chu (TW); Jui-Lin CHEN, Taipei City (TW)

(21) Appl. No.: 18/941,116

(22) Filed: Nov. 8, 2024

Related U.S. Application Data
(60) Provisional application No. 63/655,421, filed on Jun. 3, 2024.

(51) Int. Cl. H10B 10/00

(52) U.S. Cl. CPC H10B 10/125

(57) ABSTRACT

A memory cell includes first and second active regions and first, second, third, and fourth gate structures. The first, second, third, and fourth gate structures are configured to engage the first active region in forming first, second, third, and fourth transistors of a write-port of the memory cell, respectively. The second and third gate structures are configured to further engage the second active region in forming fifth and sixth transistors of the write-port of the memory cell. The memory cell also includes a fifth gate structure configured to engage the second active region in forming a seventh transistor of a read-port of the memory cell. The second active region has a first segment providing a channel region for the seventh transistor and a second segment providing channel regions for the fifth and sixth transistors. The first and second segments have different widths.

### PRIORITY DATA

This application claims priority to U.S. Provisional Patent Application No. 63/655,421 filed on Jun. 3, 2024, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Semiconductor memory is an electronic data storage device implemented on a semiconductor-based integrated circuit and has much faster access times than other types of data storage technologies. For example, static random-access memories (SRAM) devices are commonly used in integrated circuits. SRAM devices is popular in high-speed communication, image processing and system-on-chip (SOC) applications. A bit can be read from or written into the SRAM cell within a few nanoseconds, while access times for rotating storage such as hard disks is in the range of milliseconds.

When entering into deep sub-micron era, SRAM devices have become increasingly popular due to their lithography-friendly layout shapes of active regions, polysilicon lines, and metal layers. Among SRAM devices, multi-port SRAM devices have become popular. For example, a two-port (2P) SRAM device allows parallel operation, such as 1R (read) 1W (write), or 2R (read) in one cycle, and therefore has higher bandwidth than a single-port SRAM device. However, in the deep sub-micron era, SRAM cells are generally large, particularly for multi-port SRAM cells due to the insufficient area usage. With the advancement of process nodes, there is a need for a multi-port SRAM structure with cell size reduction while maintaining key performance indicators such as but not limited to voltage dynamic data retention (VDDR), maximum operating voltage (Vmax), minimum operating voltage (Vmin), alpha ratio, and beta ratio.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a perspective view and a top view of a portion of a memory device, respectively, in accordance with some embodiments of the present disclosure.

FIG. 2 illustrates a cross-sectional view of various layers of a memory device, in accordance with some embodiments of the present disclosure.

FIG. 3 illustrates a circuit schematic for a two-port SRAM cell, in accordance with some embodiments of the present disclosure.

FIGS. 4 and 5 illustrate diagrammatic layouts of the two-port SRAM cell as in FIG. 3, in accordance with some embodiments of the present disclosure.

FIGS. 6, 8, 9, 10, 12, 13, 14, 15, 16, 17, 18, 19, 20, and 21 illustrate diagrammatic layouts of an SRAM array based on the two-port SRAM cell as in FIG. 3, in accordance with some other embodiments of the present disclosure.

FIGS. 7A, 7B, and 11 illustrate cross-sectional views of portions of the SRAM array, in accordance with some embodiments of the present disclosure.

FIG. 22 shows a flow chart of a method for forming an integrated circuit having a plurality of SRAM cells, in accordance with some embodiments of the present disclosure.

FIGS. 23, 24, 25, 26, 27, 28, 29, 30, 31, 32, 33, 34, 35, 36, 37, 38, 39, 40, and 41 illustrate cross-sectional views of an integrated circuit having SRAM cells during fabrication processes according to the method of FIG. 22, in accordance with some embodiments of the present disclosure.

FIG. 42 illustrates a plane view of a channel member in a gate-all-around (GAA) transistor of an integrated circuit, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to a memory device, more particularly, multi-port static random-access memories (SRAM) cells. Two-port (2P) SRAM cells and the corresponding layouts are provided in accordance with various exemplary embodiments. Some variations of some embodiments are discussed. Furthermore, some embodiments can be applied to logic circuits.

Some exemplary embodiments are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the fin-like field-effect transistor (FinFET). The FinFET gets its name from the fin-like structure which extends from a substrate on which it is formed, and which is used to form the FET channel. Another multi-gate device, introduced in part to address performance challenges associated with the FinFET, is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

A two-port SRAM cell comprises pull-down (PD) transistors, pull-up (PU) transistors, and pass-gate (PG) transistors in a write port and one or more read-port pass-gate (R-PG) transistors in a read port. In some implementations, transistors of the same conductivity type (e.g., n-type or p-type) are formed on the same active region. An active region for a transistor refers to the area where a source region, a drain region, and a channel region under a gate structure of the transistor are formed. An active region is also referred to as an “oxide-definition (OD) region” in the context. An active region may be a three-dimensional (3D) structure for multi-gate transistors. The aggressive scaling down of IC dimensions has resulted in densely packed active regions with ever-reduced widths. To optimize transistor performance, active regions are typically set to a constant width to ensure each transistor formed thereon would have the widest available channel region, especially for p-type transistors, which are more susceptible to insufficient current drive compared to n-type transistors. In some embodiments of the present disclosure, during GAA transistor formation, a dielectric dummy layer replaces the sacrificial layers before the gate replacement process. This approach mitigates the diffusion of impurities (e.g., germanium) from the sacrificial layers into the channel layers, thereby enhancing the GAA transistor's channel integrity (e.g., flat edges with less etching loss otherwise caused by impurity diffusion) and current drive capability, particularly for p-type transistors. The improved current drive capability safeguards that p-type transistors can maintain satisfactory performance even when the active region width is not maximized. Consequently, allowing the width of the active regions to be variable provides an additional tuning parameter for fine-tuning SRAM performance.

The details of the device structures of the present disclosure are described in the attached drawings. The drawings have outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

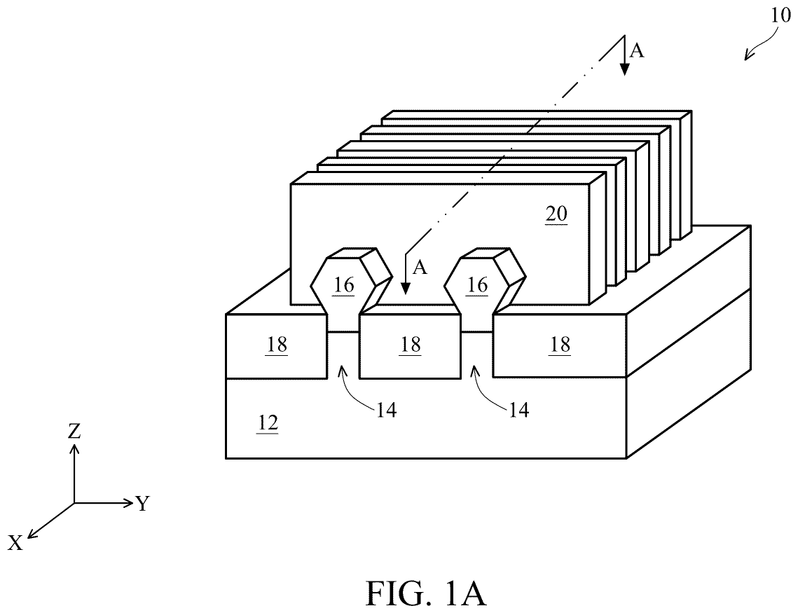

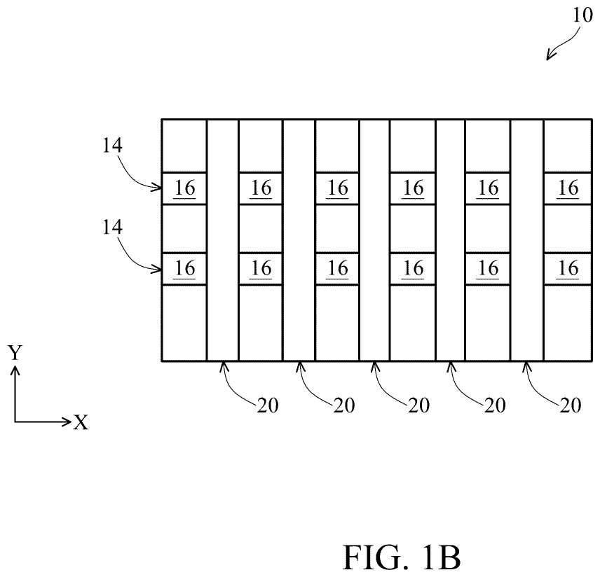

FIGS. 1A and 1B illustrate a perspective view and a top view, respectively, of a portion of an Integrated Circuit (IC) device 10, such as an SRAM device, that is implemented using GAA transistors. Referring to FIG. 1A, the IC device 10 includes a substrate 12. The substrate 12 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 12 may be a single-layer material having a uniform composition. Alternatively, the substrate 12 may include multiple material layers having similar or different compositions suitable for IC device manufacturing. In one example, the substrate 12 may be a silicon-on-insulator (SOI) substrate having a semiconductor silicon layer formed on a silicon oxide layer. In another example, the substrate 12 may include a conductive layer, a semiconductor layer, a dielectric layer, other layers, or combinations thereof. Various doped regions, such as source/drain (S/D) regions, may be formed in or on the substrate 12. The doped regions may be doped with n-type dopants, such as phosphorus or arsenic, and/or p-type dopants, such as boron, depending on design requirements. The doped regions may be formed directly on the substrate 12, in a P-well structure, in an N-well structure, in a dual-well structure, or using a raised structure. Doped regions may be formed by implantation of dopant atoms, in-situ doped epitaxial growth, and/or other suitable techniques.

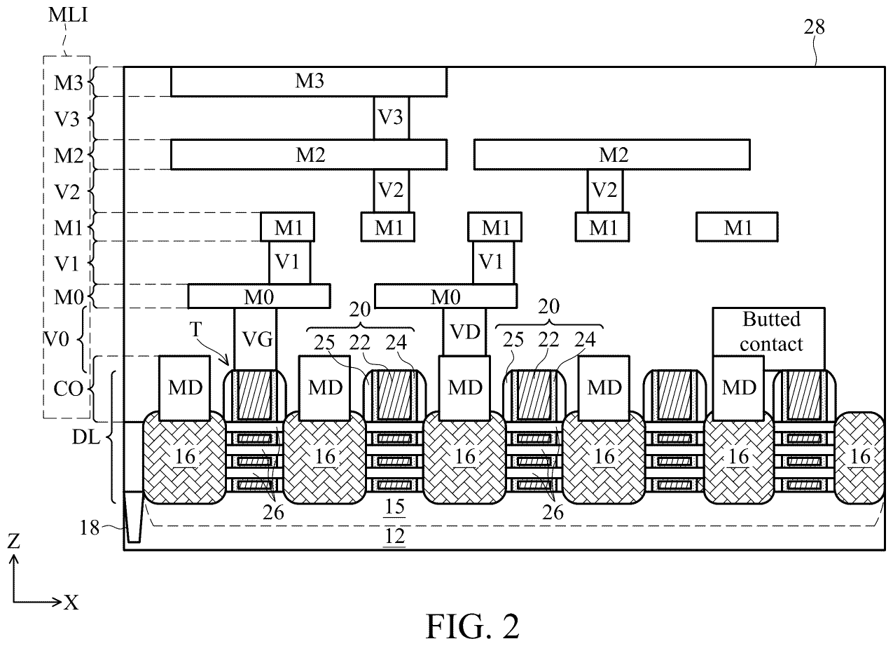

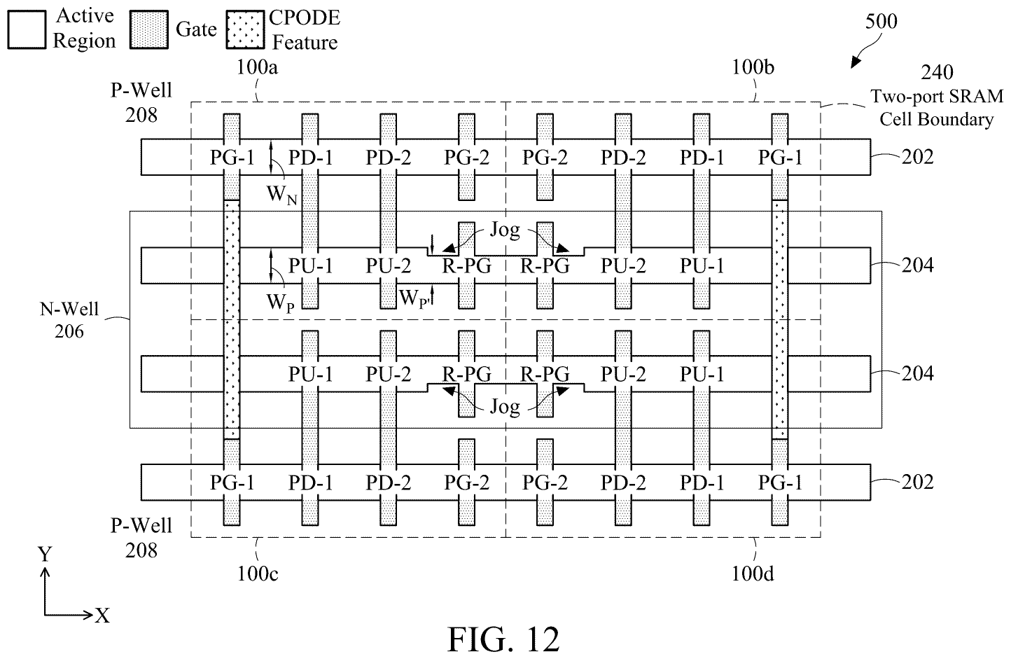

Three-dimensional active regions 14 are formed on the substrate 12. Each of the active regions 14 includes elongated nanostructures 26 (as shown in FIG. 2) vertically stacked in channel regions defined in the active region and above a fin-shape base. The fin-shape base protrudes upwardly out of the substrate 12. Source/drain features 16 are formed in source/drain regions defined in the active region and over the fin-shape base. The source/drain features 16 abut the two opposing ends of the nanostructures 26. The source/drain features 16 may include epi-layers that are epitaxially grown on the fin-shape base. Notably, although the source/drain features 16 are illustrated as having uniform width along the Y direction, this is for illustrative purposes only. As discussed below with reference to at least FIGS. 12-21, jogs may present in the active regions. These jogs may result in variations in the width of the segments of the active regions and accordingly variation in the widths of the source/drain features 16. Generally, segments of the active regions with greater width correspond to wider source/drain features 16, and vice versa.

The IC device 10 further includes isolation structures (or isolation features) 18 formed over the substrate 12. The isolation structures 18 electrically separate various components of the IC device 10. The isolation structures 18 may include silicon oxide, silicon nitride, silicon oxynitride, fluoride-doped silicate glass (FSG), a low-k dielectric material, and/or other suitable materials. In some embodiments, the isolation structures 18 may include shallow trench isolation (STI) features. In one embodiment, the isolation structures 18 are formed by etching trenches in the substrate 12 during the formation of the active regions 14. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 18. Alternatively, the isolation structures 18 may include a multi-layer structure, for example, having one or more thermal oxide liner layers.

The IC device 10 also includes gate structures (or gate stacks, or simply as gates) 20 formed over and engaging the active regions 14. The gate structures 20 may be dummy gate structures (e.g., containing an oxide gate dielectric and a polysilicon gate electrode), or they may be high-k metal gate (HKMG) structures that contain a high-k gate dielectric and a metal gate electrode, where the HKMG structures are formed by replacing the dummy gate structures. Though not depicted herein, the gate structure 20 may include additional material layers, such as an interfacial layer, a capping layer, other suitable layers, or combinations thereof.

Referring to FIG. 1B, multiple active regions 14 are oriented lengthwise along the X-direction, and multiple gate structures 20 are oriented lengthwise along the Y-direction, i.e., generally perpendicular to the active regions 14. At intersections of the active regions 14 and the gate structures 20, transistors are formed. In many embodiments, the IC device 10 includes additional features such as gate spacers disposed along sidewalls of the gate structures 20, and numerous other features.

FIG. 2 is a fragmentary diagrammatic cross-sectional view along A-A line of FIG. 1A, which shows various layers (levels) that can be fabricated over the substrate 12, according to various aspects of the present disclosure. In FIG. 2, the various layers include a device layer DL and a multilayer interconnect MLI disposed over the device layer DL. Device layer DL includes devices (e.g., transistors, resistors, capacitors, and/or inductors) and/or device components (e.g., doped wells, gate structures, and/or source/drain features). In some embodiments, device layer DL includes the substrate 12, doped regions 15 disposed in the substrate 12 (e.g., n-wells and/or p-wells), isolation features 18, and transistors T. In the depicted embodiment, transistors T include suspended nanostructures (channel members) 26 and the gate structures 20 disposed between source/drain features 16, where the gate structures 20 wrap and/or surround the suspended nanostructures 26. The nanostructures 26 may include nanosheets, nanotubes, or nanowires, or some other type of nanostructure that extends horizontally in the X-direction. Each gate structure 20 has a metal gate structure formed from a gate electrode 22 disposed over a gate dielectric 24 and gate spacers 25 disposed along sidewalls of the metal gate structure.

Multilayer interconnect MLI electrically couples various devices and/or components of device layer DL, such that the various devices and/or components can operate as specified by design requirements for the memory. In the depicted embodiment, multilayer interconnect MLI includes a contact layer (CO level), a via zero layer (V0 level), a metal zero (M0) level, a via one layer (V1 level), a metal one layer (M1 level), a via two layer (V2 level), a metal two layer (M2 level), a via three layer (V3 level), and a metal three layer (M3 level). The present disclosure contemplates multilayer interconnect MLI having more or less layers and/or levels, for example, a total number of N metal layers (levels) of the multilayer interconnect MLI with N as an integer ranging from 2 to 10. Each level of multilayer interconnect MLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of multilayer interconnect MLI, such as M1 level, are formed simultaneously. In some embodiments, conductive features at a same level of multilayer interconnect MLI have top surfaces that are substantially planar with one another and/or bottom surfaces that are substantially planar with one another. CO level includes source/drain contacts (MD) disposed in a dielectric layer 28; V0 level includes gate vias VG, source/drain contact vias VD, and butted contacts disposed in the dielectric layer 28; M0 level includes M0 metal lines disposed in dielectric layer 28, where gate vias VG connect gate structures to M0 metal lines, source/drain vias V0 connect source/drains to M0 metal lines, and butted contacts connect gate structures and source/drains together and to M0 metal lines; V1 level includes V1 vias disposed in the dielectric layer 28, where V1 vias connect M0 metal lines to M1 metal lines; M1 level includes M1 metal lines disposed in the dielectric layer 28; V2 level includes V2 vias disposed in the dielectric layer 28, where V2 vias connect M1 lines to M2 lines; M2 level includes M2 metal lines disposed in the dielectric layer 28; V3 level includes V3 vias disposed in the dielectric layer 28, where V3 vias connect M2 lines to M3 lines. FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the IC device 10 and/or SRAM cells 100 that is discussed in further detail below.

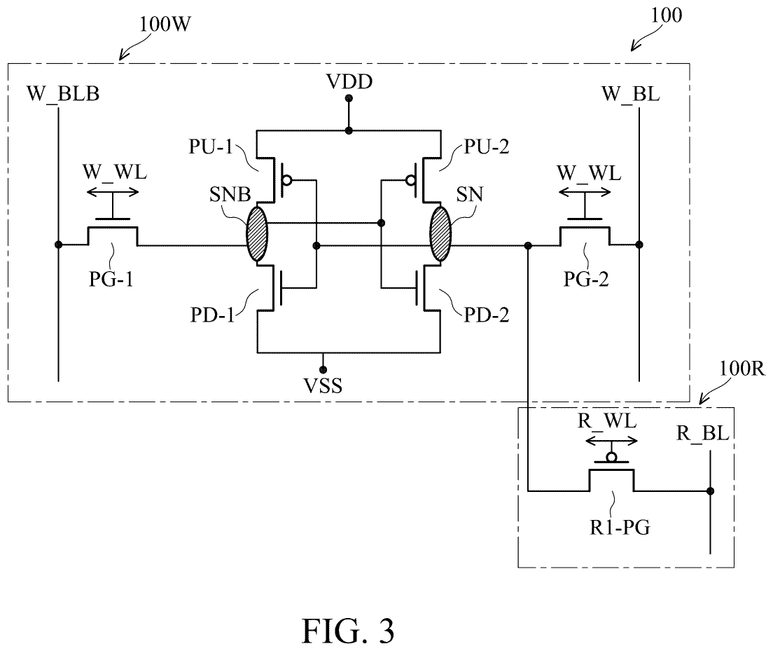

Referring now to FIG. 3, an example circuit schematic for a two-port SRAM cell 100 is shown. The two-port SRAM cell 100 includes a write-port 100W and a read-port 100R. The write-port 100W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage Vdd (also referred to as Vcc), and the sources of the pull-down transistors PD-1 and PD-2 are coupled to a voltage Vss, which may be an electrical ground in some embodiments.

The storage node SN of the data latch is coupled to a bit line W_BL of the write-port 100W through the pass-gate transistor PG-2, and the complementary storage node SNB is coupled to a complementary bit line W_BLB of the write-port 100W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 100W.

The read-port 100R of the SRAM cell 100 includes a read-port pass-gate transistor (R-PG) coupled between the bit line R_BL and the storage node SN (or to the gates of the transistors PU-1 and PD-1). The gate of the read-port pass-gate transistor R-PG is coupled to a word line R_WL of the read-port 200R. In the illustrated embodiment, the transistor R-PG is a p-type transistor. That is, in the two-port SRAM cell 100, the pass-gate transistors in a write-port are n-type transistors, and the pass-gate transistor in a read-port is a p-type transistor.

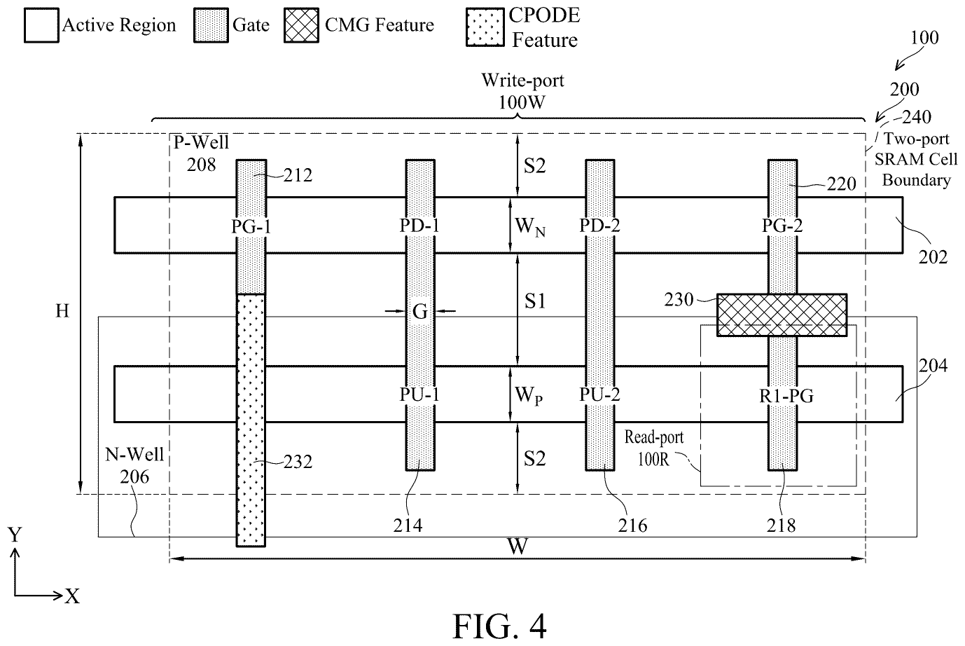

FIG. 4 illustrates a simplified diagrammatic layout 200 of the two-port SRAM cell 100, which includes the write-port 100W and the read-port 100R. The write-port 100W includes the transistors PG-1, PG-2, PU-1, PU-2, PD-1, and PD-2. The read-port 100R includes the transistor R-PG. For reasons of visual clarity and simplicity, the active regions and the gate structures of these transistors, together with some gate-cut features, are shown in FIG. 4, while the interconnection components such as contacts, vias, and metal lines are omitted from FIG. 4.

As shown in FIG. 4, the two-port SRAM cell 100 includes active regions 202 and 204. The active regions 202, 204 each extend lengthwise in the X-direction in FIG. 4. In the illustrated embodiment, the active regions 202, 204 may each include (or may be implemented as) the nanostructures 26 of FIG. 2 discussed above. In other embodiments, the active regions 202, 204 may include fin structures as well. The active region 202 are a components of the write-port 100W, and the active region 104 has a side portion as a component of the read-port 100R and rest portion as a component of the write-port 100W. In other words, the active region 204 is shared by the read-port 100R and the write-port 100W. In the illustrated embodiment, the active region 204 belong to the transistors PU-1, PU-2, R-PG, which are p-type transistors. As such, the active region 204 is formed over an N-well 206. Meanwhile, the active region 202 belongs to the transistors PG-1, PD-1, PD-2, PG-2, which are n-type transistors. As such, the active region 202 is formed over a P-well 208 (or a P-type substrate).

The two-port SRAM cell 100 further includes gate structures 212, 214, 216, 218, and 220. The gate structures 212-220 each extend lengthwise in the Y-direction in FIG. 4. The gate structures 212-220 may each include (or may be implemented as) the gate structures 20 of FIG. 2 discussed above. The gate structures 212, 214, 216, and 220 are components of the write-port 100W. The gate structure 218 is a component of the read-port 100R. The gate structures 214, 216 each extend through the two active regions 202, 204. As such, the gate structure 214 is shared by the transistors PD-1 and PU-1, and the gate structure 216 is shared by the transistors PD-2 and PU-2.

The two-port SRAM cell 100 further includes a plurality of gate-cut dielectric features, including a dielectric feature 230 extending lengthwise along the X-direction and a dielectric feature 232 extending lengthwise along the Y-direction. In the illustrated embodiment, the dielectric feature 230 is disposed between the active regions 202, 204 and abuts the gate structure 218 and the gate structure 220. Further, the dielectric feature 230 is disposed above an interface between the N-well 206 and the P-well 208. The dielectric feature 230 divides an otherwise continuous gate structure into two isolated segments corresponding to the gate structure 218 and the gate structure 220. The dielectric feature 230 is formed by filling a corresponding cut-metal-gate (CMG) trench in the position of the dielectric features. The dielectric feature 230 is also referred to as a CMG feature 230.

The dielectric feature 232 is formed in a continuous-poly-on-diffusion-edge (CPODE) process. For purposes of this disclosure, a “diffusion edge” may be equivalently referred to as an active edge, where for example an active edge abuts adjacent active regions. The dielectric feature 232 is also referred to as a CPODE feature 232. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion of the otherwise continuous gate structure and is confined between the opposing gate spacers of the replaced portion of the gate structure. As a comparison, a CMG feature truncates the otherwise continuous gate structure and extends into adjacent areas of the gate structure. In FIG. 4, the CPODE feature 232 abuts the gate structure 212 and is aligned with the gate structure 212. The CPODE feature 232 extends along the Y-direction and across the N-well 206 into another P-well 208 of an adjacent SRAM cell. That is, two adjacent SRAM cells may share the CPODE feature 232. Further, the CPODE feature 232 may extend downwardly deeper into the underneath substrate than the CMG feature 230, in some embodiments.

Referring still to FIG. 4, a boundary 240 of the two-port SRAM cell 100 is illustrated using broken lines. It's worth noting that some active regions and gate structures may extend beyond this illustrated boundary 240, as these components may also form parts of adjacently located SRAM cells. The boundary 240 is rectangular, with its length in the X-direction exceeding that in the Y-direction. The first dimension of the boundary 240 along the X-direction is denoted as the cell width W, while the second dimension along the Y-direction is denoted as the cell height H. In the context of a memory array where the two-port SRAM cell 100 is repeated, the cell width W may be referred to as the memory cell pitch along the X-direction, and the cell height H as the memory cell pitch along the Y-direction.

The cell size of the two-port SRAM cell 100 is W×H, in which the cell width W is about 4 times a poly pitch (e.g., a center-to-center distance between two adjacent gate structures along the X-direction) and the cell heigh H is about 2 times an isolation pitch (e.g., a center-to-center distance between two adjacent STI features along the Y-direction). Denoting an area of one poly pitch times one isolation pitch as a unit area, each unit area includes an intersection of a gate structure and an active region, and the two-port SRAM cell 100 utilizes a cell size of about 8 times a unit area in accommodating the seven transistors, namely the transistors PG-1, PG-2, PU-1, PU-2, PD-1, PD-2, and R-PG. The area utilization rate is considered high as there is only one unit area not utilized for forming a functional transistor but hosting an intersection of a CPODE feature and an active region instead.

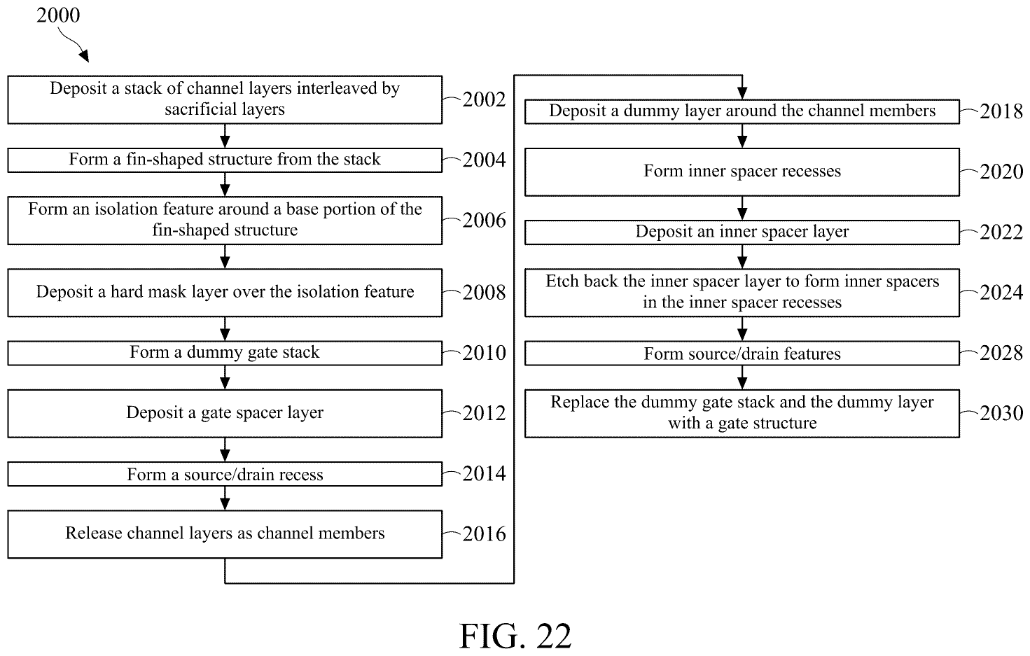

The active region 202 for n-type transistors has a width denoted as W_{N}, the active region 204 for p-type transistors has a width denoted as W_{P}, each of the gate structures 212-220 has a critical dimension (CD) or gate width denoted as G. In some embodiments, G ranges from about 10 nm to about 20 nm, W_{N} ranges from about 11 nm to about 35 nm, and W_{P} ranges from about 11 nm to about 35 nm. In some embodiments, W_{P} equals W_{N} (W_{P}=W_{N}) to balance read port speed and write port speed. In some embodiments, W_{P} is larger than W_{N} (W_{P}>W_{N}) to better accommodate read port speed needs. In some embodiments, W_{P} is smaller than W_{N} (W_{P}<W_{N}) to better accommodate write port speed needs. P-type transistors typically have lower current drive capability than n-type transistors due to the limited p-type carrier mobility. To address this, the active region 204 may traditionally have a constant width W_{P}, ensuring each p-type transistor formed thereon has the widest available channel region. However, the present disclosure implements a modified approach in GAA transistor manufacturing (discussed in detail later with respect to FIGS. 22-42), which improves etch selectivity during the gate replacement process. This enhancement significantly boosts the current drive capability of GAA transistors, particularly for p-type transistors. Consequently, this improvement allows some transistors formed on the active region 204 to have varying widths without compromising current drive capability. In other words, the active region 204 may now feature a variable W_{P} in certain embodiments, a concept that will be further elaborated later in the present disclosure.

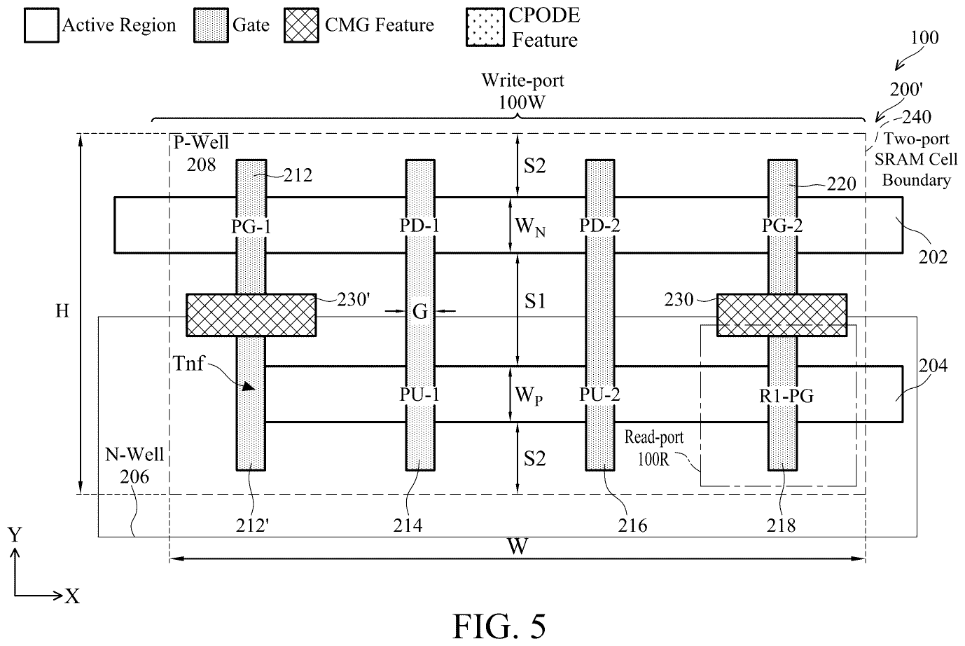

FIG. 5 illustrates an alternative diagrammatic layout 200′ of the two-port SRAM cell 100. Many aspects of the alternative layout 200′ are the same as the layout 200 illustrated in FIG. 4. For reasons of clarity and consistency, similar elements appearing in FIGS. 4 and 5 are labeled the same, and the details of these elements are not necessarily repeated again below. Different from the layout 200, in the alternative layout 200′, there is no CPODE feature 232 in the alternative layout 200′ but an extra CMG feature 230′ and an extra gate structure 212′. The CMG feature 230′ is disposed between the active regions 202, 204 and abuts the gate structure 212 and the gate structure 212′. Further, the dielectric feature 230′ is disposed above an interface between the N-well 206 and the P-well 208. The dielectric feature 230′ divides an otherwise continuous gate structure into two isolated segments corresponding to the gate structure 212 and the gate structure 212′. The gate structure 212′ covers an edge of one end of the active region 204. Meanwhile, the end of the active region 204 does not extend along the X-direction beyond the other side of the gate structure 212. As a result, it is a non-functional transistor (denoted as T_{nf}) formed at the intersection of the end of the action region 204 and the gate structure 212′.

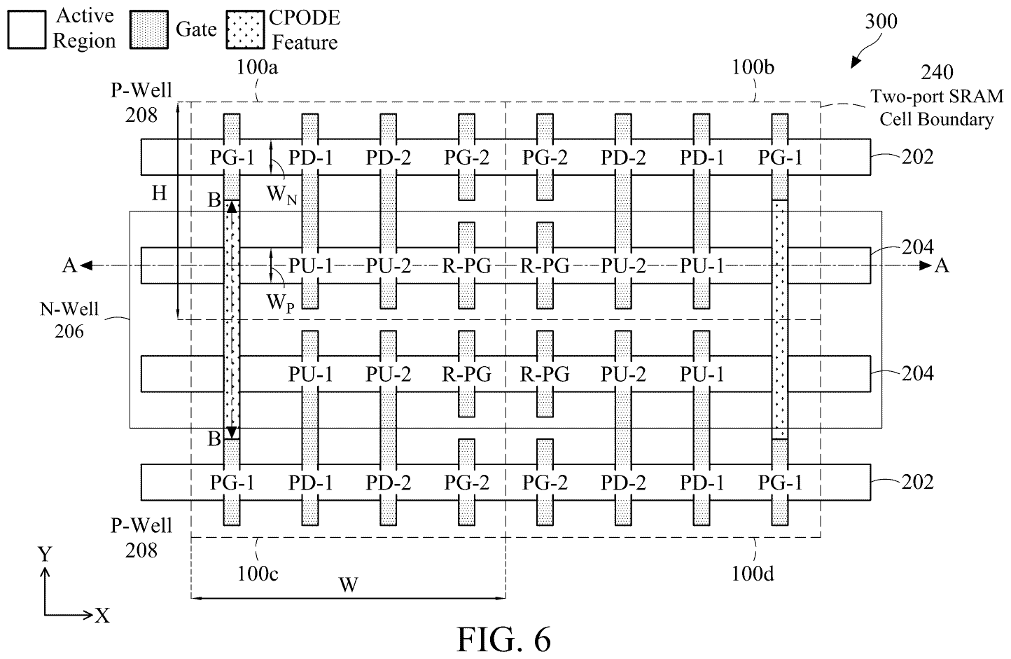

FIG. 6 illustrates a layout 300 of an SRAM array according to the present disclosure. Referring to FIG. 6, a plurality of two-port SRAM cells 100a, 100b, 100c, and 100d are arranged in the X-direction and the Y-direction, forming a 2×2 array of SRAM cells. Each SRAM cell in the array may use the layout 200 as depicted in FIG. 4. In some embodiments, two adjacent SRAM cells in the X-direction are line symmetric with respect to a common boundary therebetween, and two adjacent SRAM cells in the Y-direction are line symmetric with respect to a common boundary therebetween. That is, the SRAM cell 100b is a duplicate cell for the SRAM cell 100a but flipped over the Y-axis; the SRAM cell 100c is a duplicate cell for the SRAM cell 100a but flipped over the X-axis; and the SRAM cell 100d is a duplicate cell for the SRAM cell 100b but flipped over the X-axis. FIG. 6 has been simplified for the sake of clarity to better understand the inventive concepts of the present disclosure. For example, active regions, gate structures, CPODE features, N-well, P-well, and cell boundaries for shown, while some other features are omitted. As depicted in FIG. 6, the layout 300 of the SRAM array includes well regions 206 and 208 alternately arranged along the Y-axis. In other words, every P-well 208 is next to an N-well 206 which is next to another P-well 208, and this pattern repeats. In the illustrated embodiment as in FIG. 6, the gate structures in each two-port SRAM cells do not extend beyond the respective cell boundary, and each CPODE feature is shared by two neighboring SRAM cells arranged in the Y-direction.

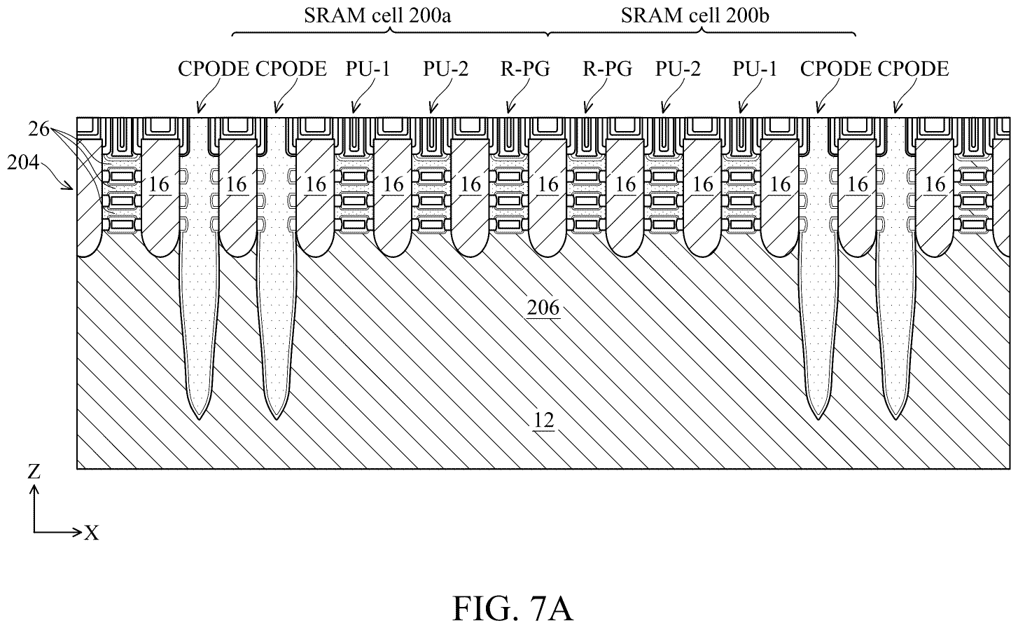

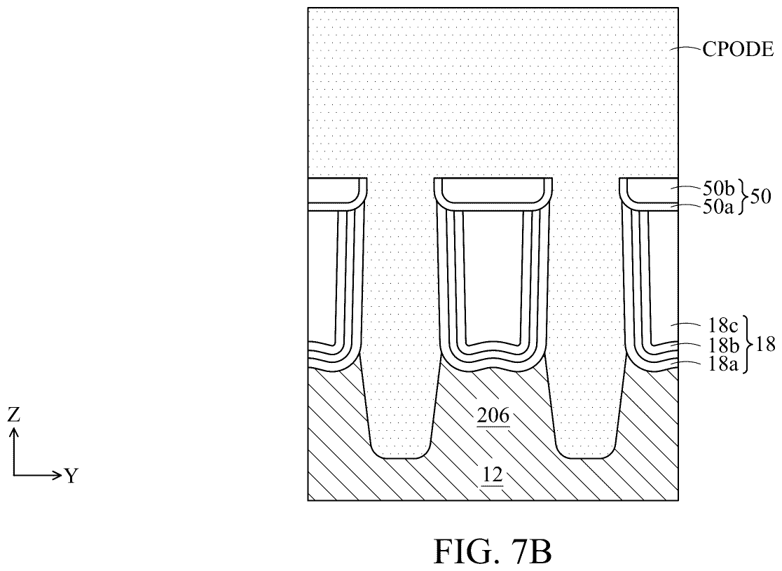

FIG. 7A is a fragmentary diagrammatic cross-sectional view along A-A line of FIG. 6, which cuts the active region 204 along its lengthwise direction, according to various aspects of the present disclosure. FIG. 7B is a fragmentary diagrammatic cross-sectional view along B-B line of FIG. 6, which cuts a CPODE feature, according to various aspects of the present disclosure. Referring to FIGS. 7A and 7B collectively, the active region 204 extends through the SRAM cells 100a, 100b but sandwiched by the CPODE feature in the SRAM cell 100a and the CPODE feature in the SRAM cell 100b. The CPODE features replace the otherwise metal gate structures closest to the cell edges. The distance between the CPODE feature in the SRAM cell 100a and the CPODE feature in the SRAM cell 100b (CPODE-to-CPODE pitch) is 7 times a poly pitch. To better illustrate the arrangement of the CPODE features, an extra CPODE feature in an SRAM cell laid to the left of the SRAM cell 100a and an extra CPODE feature in an SRAM cell laid to the right of the SRAM cell 100b along the X-direction are also depicted in FIG. 7A.

Between the CPODE feature in the SRAM cell 100a and the CPODE feature in the SRAM cell 100b, the active region 204 includes channel regions that is comprised of the nanostructures 26 and source/drain features 16 abut the ends of the nanostructures 26. The gate structures wrap around the nanostructures 26 and form the transistors PU-1, PU-2, R-PG in the SRAM cell 100a and the transistors R-PG, PU-2, PU-1 in the SRAM cell 100b. The active region 204 is disposed over the N-well 206, and the active region 202 is disposed over the P-well 208. The source/drain features 16 formed on the active region 204 is p-type epitaxial features, and the source/drain features 16 formed on the active region 202 is n-type epitaxial features. The isolation structures 18 may include shallow trench isolation (STI) features. In one embodiment, the isolation structures 18 are formed by etching trenches in the substrate 12 during the formation of the active regions 202 and 204. The isolation structures 18 may include a multi-layer structure, for example, having an oxide liner 18a (e.g., a thermal SiO₂ liner), a first dielectric layer 18b (e.g., SiOCN), and a second dielectric layer 18c (e.g., SiO₂). Notably, a hard mask layer 50 is deposited on the isolation structure 18. A composition of the hard mask layer 50 is different from a composition of the isolation feature 18 to ensure that each one of them may be selectively etched without substantially damaging the other one. The hard mask layer 50 may be a single layer or a multi-layer. For example, the hard mask layer 50 may include an oxide liner 50a (e.g., SiO₂ or SiON) and a nitride layer 50b (e.g., SiN or SiON) disposed over the oxide liner 50a. The presence of the hard mask layer 50 stacking between the isolation feature 18 and the CPODE feature is a distinguishing characteristic of the modified approach in GAA transistor manufacturing being adopted (discussed in detail later with respect to FIGS. 22-42).

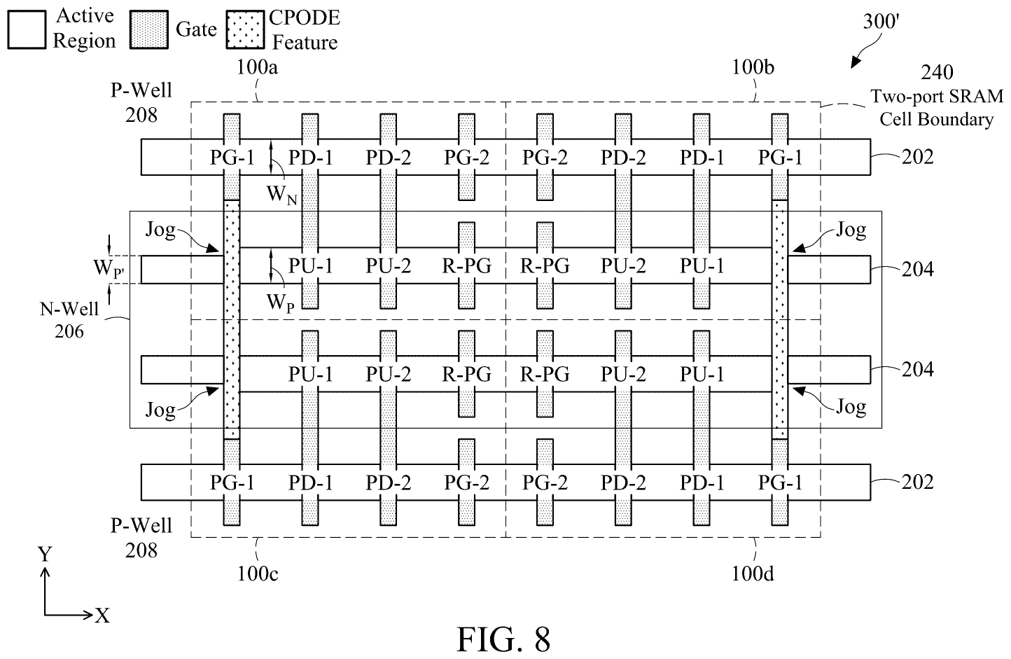

FIG. 8 illustrates an alternative layout 300′ of the SRAM array. Many aspects of the alternative layout 300′ are the same as the layout 300 illustrated in FIG. 6. For reasons of clarity and consistency, similar elements appearing in FIGS. 6 and 8 are labeled the same, and the details of these elements are not necessarily repeated again below. Different from the layout 300, in the alternative layout 300′, the end portions of the active region 204 extending beyond the CPODE features have a reduced width W_{P}′ (W_{P}′<W_{P}). The location where the width of the active region changes abruptly are referred to as “jogs.” In the depicted embodiment, the jogs of the active region 204 are situated beneath the CPODE features, all positioned on one side of the active region 204 that faces the adjacent active region 202. The opposite side of the active region 204, which faces the adjacent active region 204, is free of jogs.

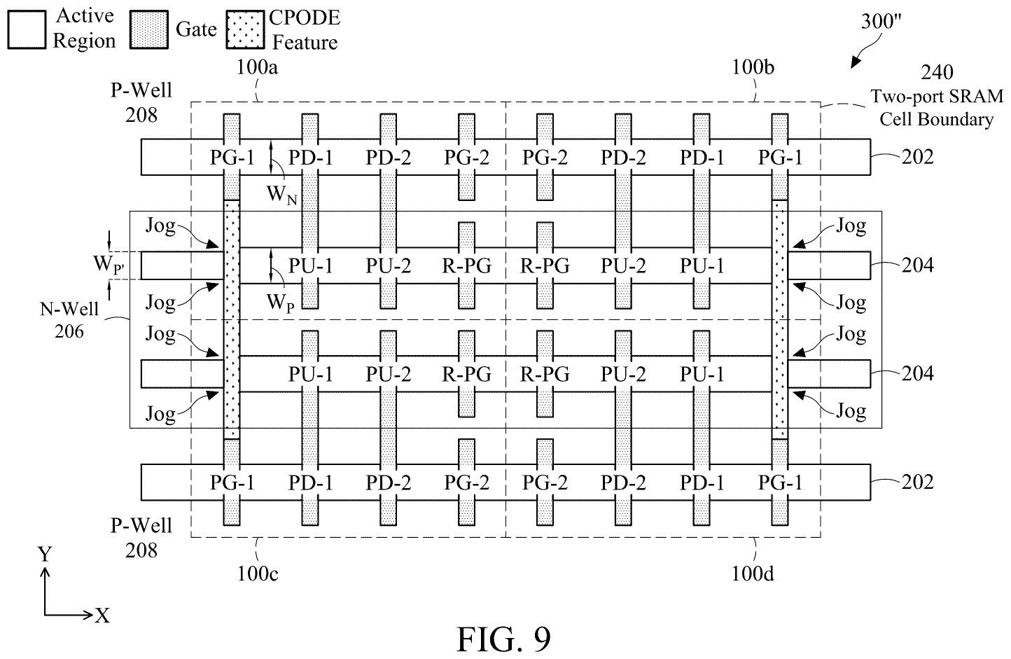

FIG. 9 illustrates an alternative layout 300″ of the SRAM array. Many aspects of the alternative layout 300″ are the same as the layout 300′ illustrated in FIG. 8. For reasons of clarity and consistency, similar elements appearing in FIGS. 8 and 9 are labeled the same, and the details of these elements are not necessarily repeated again below. Different from the layout 300′, in the alternative layout 300″, the jogs of the active region 204 are positioned on both sides of the active region 204.

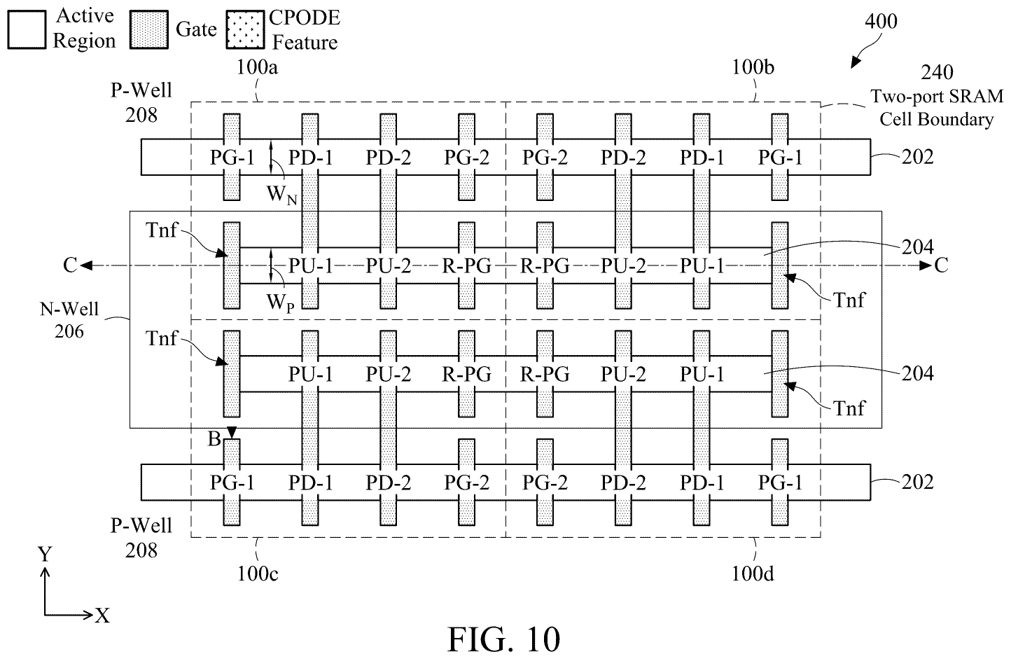

FIG. 10 illustrates an alternative layout 400 of the SRAM array. Referring to FIG. 10, a plurality of two-port SRAM cells 100a, 100b, 100c, and 100d are arranged in the X-direction and the Y-direction, forming a 2×2 array of SRAM cells. Each SRAM cell in the array may use the layout 200′ as depicted in FIG. 5. Many aspects of the alternative layout 400 are the same as the layout 300 illustrated in FIG. 6. For reasons of clarity and consistency, similar elements appearing in FIGS. 6 and 10 are labeled the same, and the details of these elements are not necessarily repeated again below. Different from the layout 300, in the alternative layout 400, there are no CPODE features in the alternative layout 400 but extra gate structures covering edges of the ends of the active regions 204 in forming non-function transistors T_{nf}. Meanwhile, the end of the active region 204 does not extend along the X-direction beyond the other side of the respective extra gate structure.

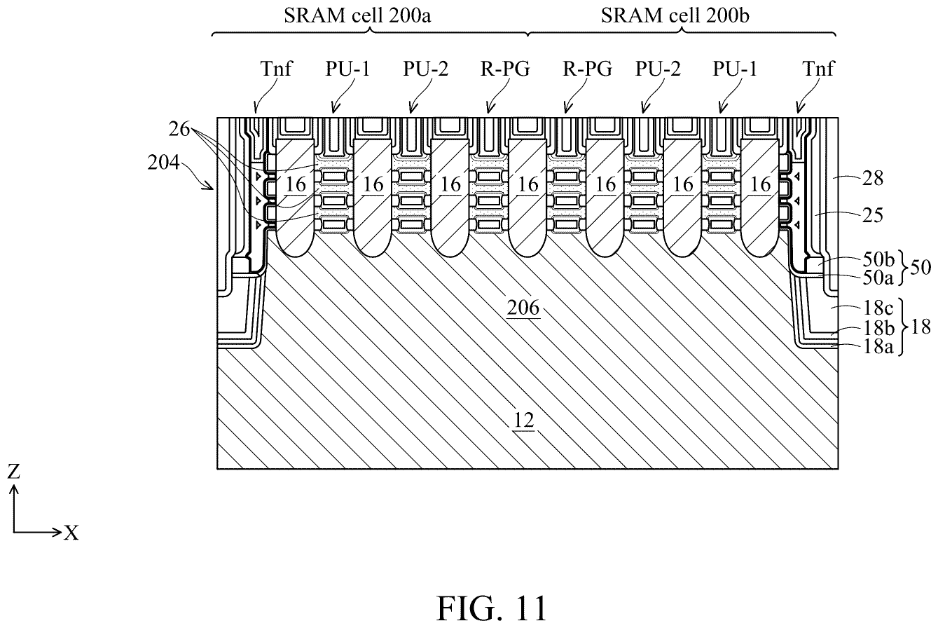

FIG. 11 is a fragmentary diagrammatic cross-sectional view along C-C line of FIG. 10, which cuts the active region 204 along its lengthwise direction, according to various aspects of the present disclosure. Different from the cross-sectional view as depicted in FIG. 7A, the active region 204 is sandwiched between the isolation features 18 and the extra gate structures of the non-functional transistors T_{nf} that are disposed on the ends of the active region 204. The hard mask layer 50 is deposited on the isolation feature 18. The gate spacers 25 and a dielectric layer 28 (may include a contact etch stop layer (CESL) and an interlayer dielectric (ILD) layer) are disposed on the hard mask layer 50. The presence of the hard mask layer 50 stacking between the isolation feature 18 and the gate spacers 25 is a distinguishing characteristic of the modified approach in GAA transistor manufacturing being adopted (discussed in detail later with respect to FIGS. 22-42).

FIG. 12 illustrates an alternative layout 500 of the SRAM array, which is by modifying the layout 300 in FIG. 6. Many aspects of the alternative layout 500 are the same as the layout 300 illustrated in FIG. 6. For reasons of clarity and consistency, similar elements appearing in FIGS. 6 and 12 are labeled the same, and the details of these elements are not necessarily repeated again below. Different from the layout 300, in the alternative layout 500, the active region 204 does not have a constant width W_{P}, but a segment providing the channel regions for the R-PG transistors with a smaller width W_{P}′ (W_{P}>W_{P}′). In furtherance of the embodiments, the width W_{N} of the active region 202 equals the width W_{P} (W_{N}=W_{P}). As discussed above, the width W_{N} may alternatively be smaller or larger than the width W_{P} depending on device performance needs. By providing the pull-up transistors PU-1, PU-2 with a wider channel region and the read-port pass-gate transistor R-PG with a narrower channel region, the VDDR of the SRAM device may be improved, such as by about 30 mV to about 80 mV. A ratio of W_{P}′ over W_{P} (W_{P}′/W_{P}) may range from about 0.75 to about 1 (0.75<W_{P}′/W_{P}<1), in some embodiments. The range is not trivial or arbitrary. If the ratio is not larger than about 0.75, the channel width for the transistor R-PG may be too small to provide sufficient current drive capability; if the ratio is not smaller than 1, the transistors PU-1, PU-2 won't have stronger current drive capability than the transistor R-PG to achieve the VDDR improvement. In some embodiments, the difference between the widths (W_{P}−W_{P}′) may range from about 2 nm to about 8 nm. In the depicted embodiment, the jogs of the active region 204 are all positioned on one side of the active region 204 that faces the adjacent active region 202. The opposite side of the active region 204, which faces the adjacent active region 204, is free of jogs. Each jog of the active region 204 is position between the gate structure of the transistor PU-2 and the gate structure of the transistor R-PG along the X-direction, such as in the middle point between the two gate structures.

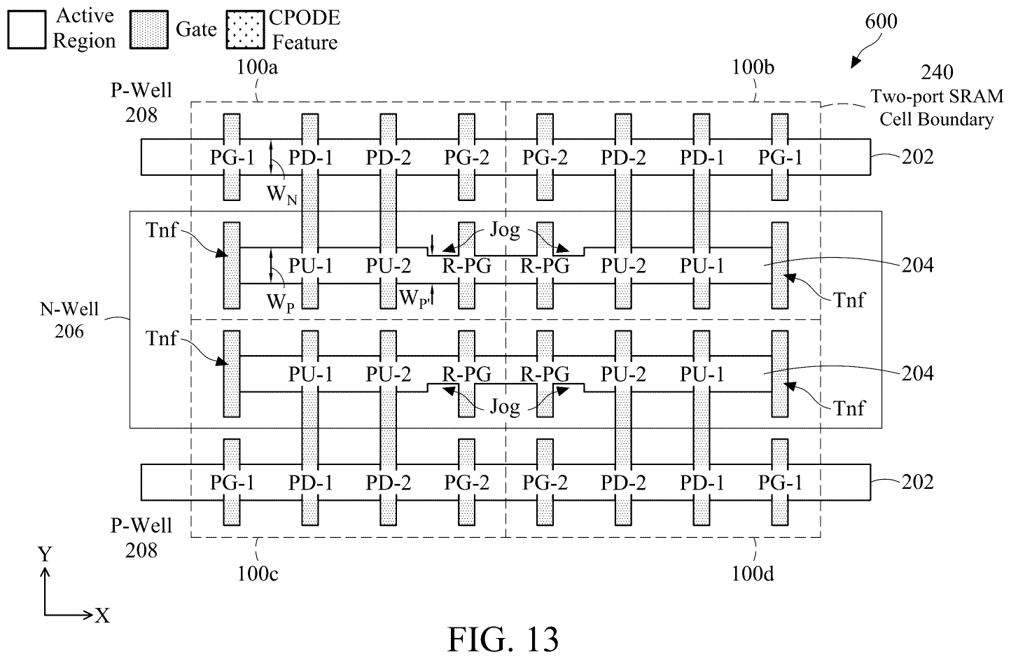

FIG. 13 illustrates an alternative layout 600 of the SRAM array, which is by modifying the layout 400 in FIG. 10. Many aspects of the alternative layout 600 are the same as the layout 400 illustrated in FIG. 10. For reasons of clarity and consistency, similar elements appearing in FIGS. 10 and 13 are labeled the same, and the details of these elements are not necessarily repeated again below. Different from the layout 400, in the alternative layout 600, the active region 204 does not have a constant width W_{P}, but a segment providing the channel regions for the R-PG transistors with a smaller width W_{P}′ (W_{P}>W_{P}′). In furtherance of the embodiments, the width W_{N} of the active region 202 equals the width W_{P} (W_{N}=W_{P}). As discussed above, the width W_{N} may alternatively be smaller or larger than the width W_{P} depending on device performance needs. By providing the pull-up transistors PU-1, PU-2 with a wider channel region and the read-port pass-gate transistor R-PG with a narrower channel region, the VDDR of the SRAM device may be improved, such as by about 30 mV to about 80 mV. A ratio of W_{P}′ over W_{P} (W_{P}′/W_{P}) may range from about 0.75 to about 1 (0.75<W_{P}′/W_{P}<1), in some embodiments. The range is not trivial or arbitrary. If the ratio is not larger than about 0.75, the channel width for the transistor R-PG may be too small to provide sufficient current drive capability; if the ratio is not smaller than 1, the transistors PU-1, PU-2 won't have stronger current drive capability than the transistor R-PG to achieve the VDDR improvement. In some embodiments, the difference between the widths (W_{P}-W_{P}′) may range from about 2 nm to about 8 nm. In the depicted embodiment, the jogs of the active region 204 are all positioned on one side of the active region 204 that faces the adjacent active region 202. The opposite side of the active region 204, which faces the adjacent active region 204, is free of jogs. Each jog of the active region 204 is position between the gate structure of the transistor PU-2 and the gate structure of the transistor R-PG along the X-direction, such as in the middle point between the two gate structures.

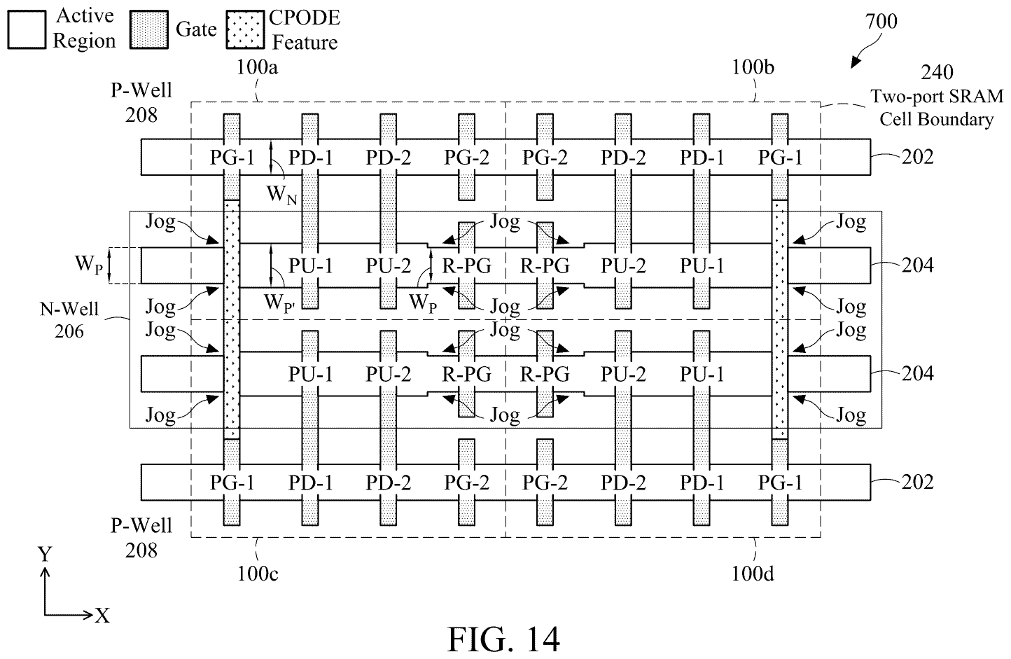

FIG. 14 illustrates an alternative layout 700 of the SRAM array, which is by modifying the layout 300 in FIG. 6. Many aspects of the alternative layout 700 are the same as the layout 300 illustrated in FIG. 6. For reasons of clarity and consistency, similar elements appearing in FIGS. 6 and 14 are labeled the same, and the details of these elements are not necessarily repeated again below. Different from the layout 300, in the alternative layout 700, the active region 204 does not have a constant width W_{P}, but a segment providing the channel regions for the pull-up transistors PU-1, PU-2 are expanded to have a larger width W_{P}′ (W_{P}′ >W_{P}). In furtherance of the embodiments, the width W_{N} of the active region 202 equals the width W_{P} (W_{N}=W_{P}). The width W_{N} may alternatively be smaller or larger than the width W_{P} depending on device performance needs, but smaller than the width W_{P}′. By providing the pull-up transistors PU-1, PU-2 with a wider channel region and the read-port pass-gate transistor R-PG with a narrower channel region, the VDDR of the SRAM device may be improved, such as by about 30 mV to about 80 mV. A ratio of W_{P}′ over W_{P} (W_{P}′/W_{P}) may range from about 1 to about 1.25 (1<W_{P}′/W_{P}<1.25), in some embodiments. The range is not trivial or arbitrary. If the ratio is not smaller than about 1.25, the channel width for the transistors PU-1, PU-2 may be too large and become too close to the adjacent active region 202; if the ratio is not larger than 1, the transistors PU-1, PU-2 won't have stronger current drive capability than the transistor R-PG to achieve the VDDR improvement. In some embodiments, the difference between the widths (W_{P}′−W_{P}) may range from about 2 nm to about 10 nm. In the depicted embodiment, the jogs of the active region 204 are positioned on both sides of the active region 204. Each jog of the active region 204 is position either between the gate structure of the transistor PU-2 and the gate structure of the transistor R-PG along the X-direction, such as in the middle point between the two gate structures, or under the respective CPODE feature.

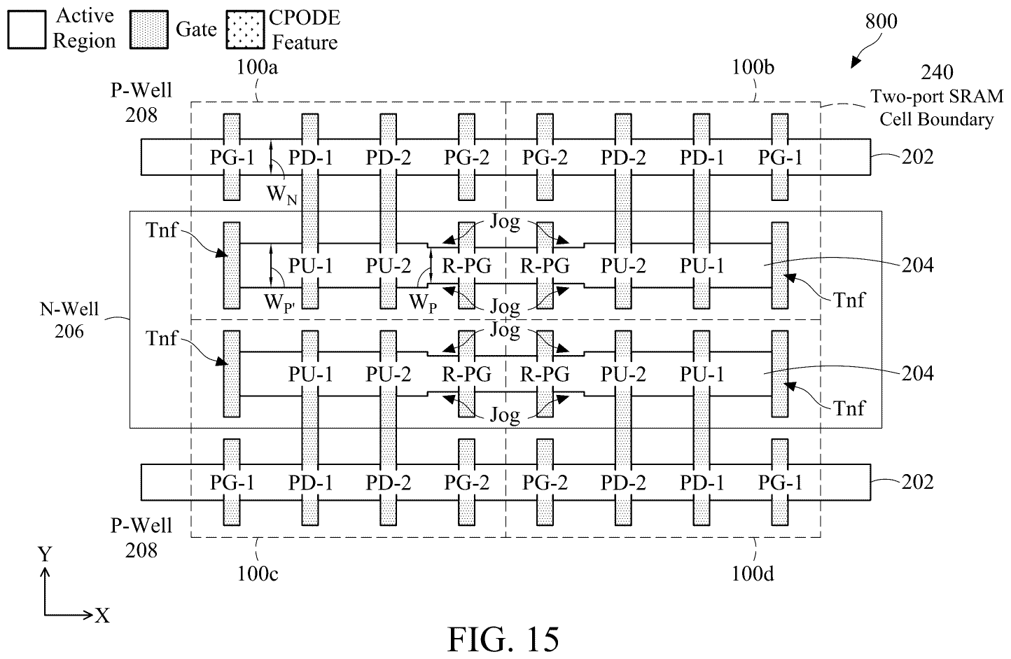

FIG. 15 illustrates an alternative layout 800 of the SRAM array, which is by modifying the layout 400 in FIG. 10. Many aspects of the alternative layout 800 are the same as the layout 400 illustrated in FIG. 10. For reasons of clarity and consistency, similar elements appearing in FIGS. 10 and 15 are labeled the same, and the details of these elements are not necessarily repeated again below. Different from the layout 400, in the alternative layout 800, the active region 204 does not have a constant width W_{P}, but a segment providing the channel regions for the pull-up transistors PU-1, PU-2 are expanded to have a larger width W_{P}′ (W_{P}′>W_{P}). In furtherance of the embodiments, the width W_{N} of the active region 202 equals the width W_{P} (W_{N}=W_{P}). The width W_{N} may alternatively be smaller or larger than the width W_{P} depending on device performance needs, but smaller than the width W_{P}′. By providing the pull-up transistors PU-1, PU-2 with a wider channel region and the read-port pass-gate transistor R-PG with a narrower channel region, the VDDR of the SRAM device may be improved, such as by about 30 mV to about 80 mV. A ratio of W_{P}′ over W_{P} (W_{P}′/W_{P}) may range from about 1 to about 1.25 (1<W_{P}′/W_{P}<1.25), in some embodiments. The range is not trivial or arbitrary. If the ratio is not smaller than about 1.25, the channel width for the transistors PU-1, PU-2 may be too large and become too close to the adjacent active region 202; if the ratio is not larger than 1, the transistors PU-1, PU-2 won't have stronger current drive capability than the transistor R-PG to achieve the VDDR improvement. In some embodiments, the difference between the widths (W_{P}′−W_{P}) may range from about 2 nm to about 10 nm. In the depicted embodiment, the jogs of the active region 204 are positioned on both sides of the active region 204. Each jog of the active region 204 is position between the gate structure of the transistor PU-2 and the gate structure of the transistor R-PG along the X-direction, such as in the middle point between the two gate structures.

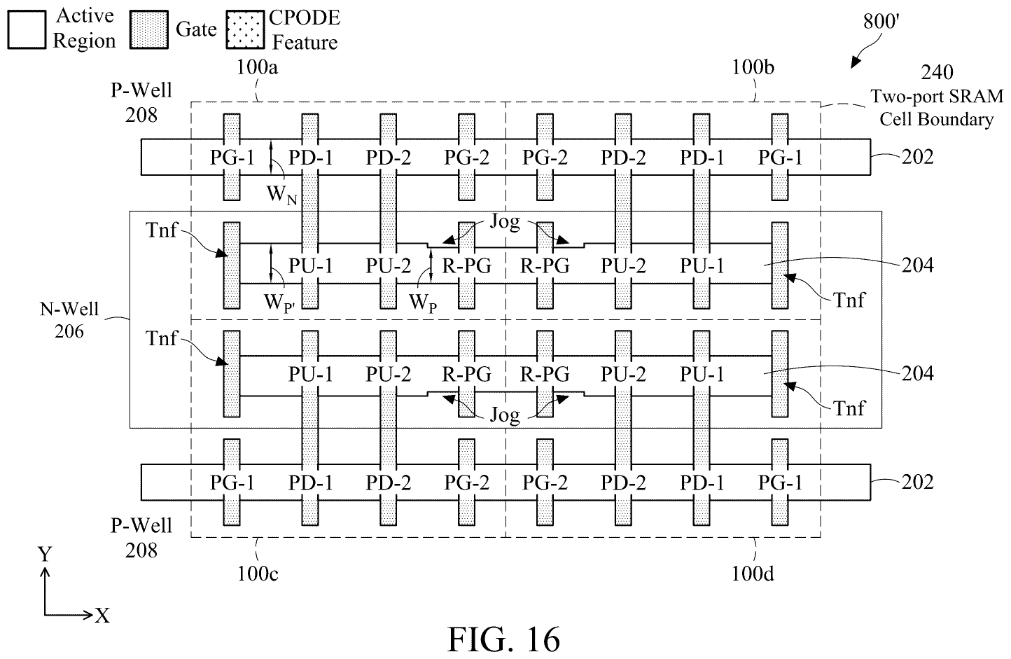

FIG. 16 illustrates an alternative layout 800′ of the SRAM array, which is a variation of the layout 800 in FIG. 15. Different from the layout 800, in the alternative layout 800′, the jogs of the active region 204 are all positioned on one side of the active region 204 that faces the adjacent active region 202. The opposite side of the active region 204, which faces the adjacent active region 204, is free of jogs.

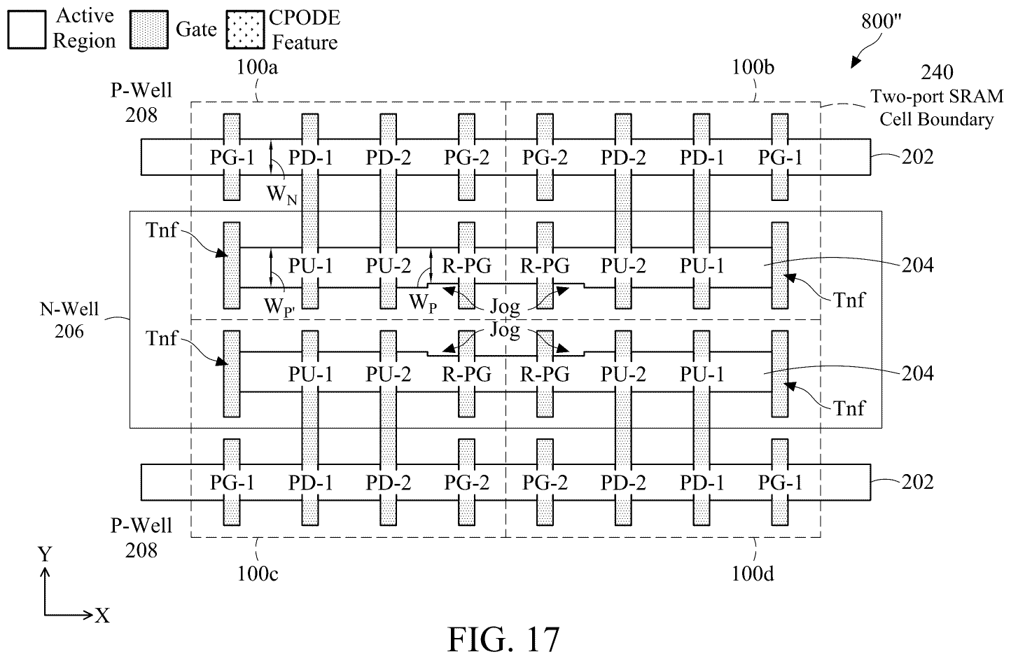

FIG. 17 illustrates an alternative layout 800″ of the SRAM array, which is a variation of the layout 800 in FIG. 15. Different from the layout 800, in the alternative layout 800″, the jogs of the active region 204 are all positioned on one side of the active region 204 that faces the adjacent active region 204. The opposite side of the active region 204, which faces the adjacent active region 202, is free of jogs. The choice of the layouts 800, 800′, and 800″ mainly depends on the distance requirement between the adjacent same type and opposite type active regions, particularly when the design rules have set limitations on minimum distances between the adjacent same type and/or opposite type active regions.

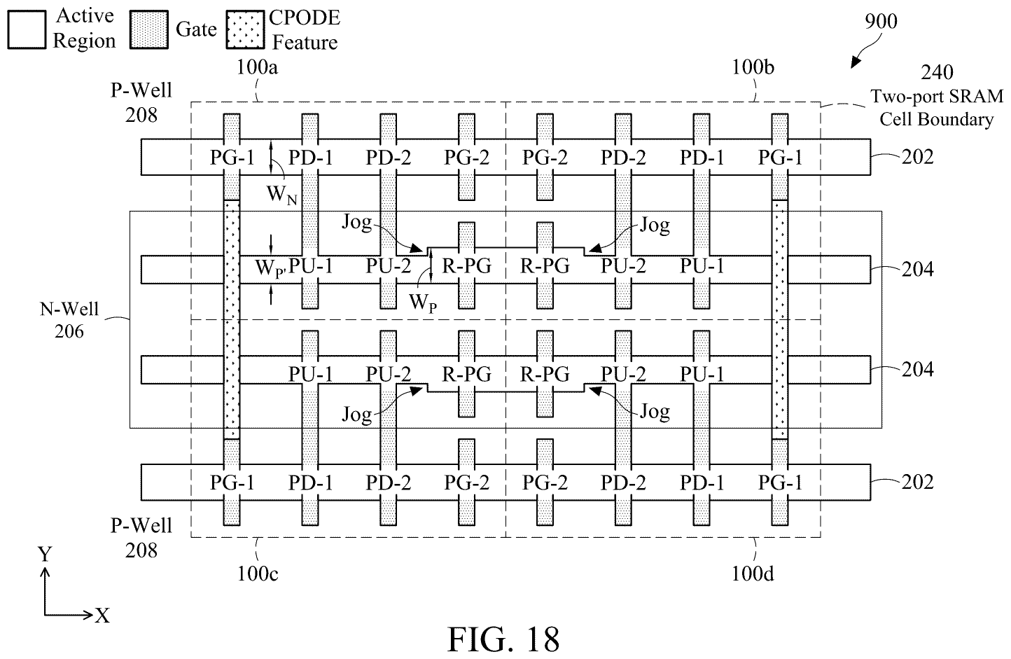

FIG. 18 illustrates an alternative layout 900 of the SRAM array, which is by modifying the layout 300 in FIG. 6. Many aspects of the alternative layout 900 are the same as the layout 300 illustrated in FIG. 6. For reasons of clarity and consistency, similar elements appearing in FIGS. 6 and 18 are labeled the same, and the details of these elements are not necessarily repeated again below. Different from the layout 300, in the alternative layout 900, the active region 204 does not have a constant width W_{P}, but a segment providing the channel regions for the pull-up transistors PU-1, PU-2 with a smaller width W_{P}′ (W_{P}>W_{P}′). In furtherance of the embodiments, the width W_{N} of the active region 202 equals the width W_{P} (W_{N}=W_{P}). The width W_{N} may alternatively be smaller or larger than the width W_{P} depending on device performance needs, but larger than the width W_{P}′. By providing the pull-up transistors PU-1, PU-2 with a narrower channel region and the read-port pass-gate transistor R-PG with a larger channel region, the Vmin of the SRAM device may be improved. A ratio of W_{P}′ over W_{P} (W_{P}′/W_{P}) may range from about 0.75 to about 1 (0.75<W_{P}′/W_{P}<1), in some embodiments. The range is not trivial or arbitrary. If the ratio is not larger than about 0.75, the channel width for the transistors PU-1, PU-2 may be too small to provide sufficient current drive capability; if the ratio is larger than 1, the transistors R-PG won't have stronger current drive capability than the transistors PU-1, PU-2 to achieve the Vmin improvement. In some embodiments, the difference between the widths (W_{P}′−W_{P}) may range from about 2 nm to about 8 nm. In the depicted embodiment, the jogs of the active region 204 are all positioned on one side of the active region 204 that faces the adjacent active region 202. The opposite side of the active region 204, which faces the adjacent active region 204, is free of jogs. Each jog of the active region 204 is position between the gate structure of the transistor PU-2 and the gate structure of the transistor R-PG along the X-direction, such as in the middle point between the two gate structures.

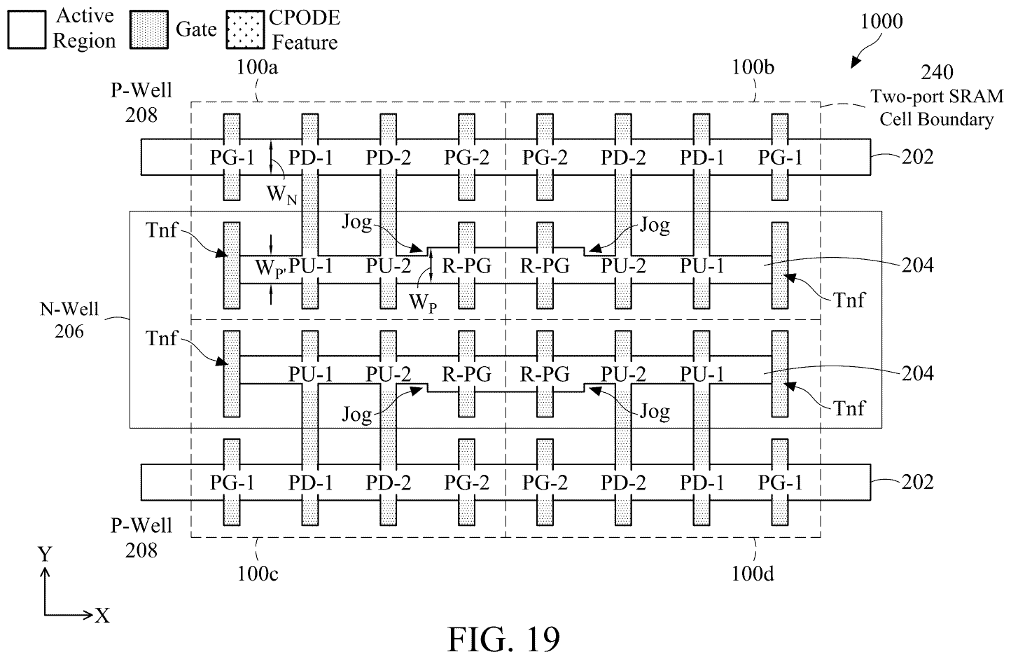

FIG. 19 illustrates an alternative layout 1000 of the SRAM array, which is by modifying the layout 400 in FIG. 10. Many aspects of the alternative layout 1000 are the same as the layout 400 illustrated in FIG. 10. For reasons of clarity and consistency, similar elements appearing in FIGS. 10 and 19 are labeled the same, and the details of these elements are not necessarily repeated again below. Different from the layout 400, in the alternative layout 1000, the active region 204 does not have a constant width W_{P}, but a segment providing the channel regions for the pull-up transistors PU-1, PU-2 with a smaller width W_{P}′ (W_{P}>W_{P}′). In furtherance of the embodiments, the width W_{N} of the active region 202 equals the width W_{P} (W_{N}=W_{P}). The width W_{N} may alternatively be smaller or larger than the width W_{P} depending on device performance needs, but larger than the width W_{P}′. By providing the pull-up transistors PU-1, PU-2 with a narrower channel region and the read-port pass-gate transistor R-PG with a larger channel region, the Vmin of the SRAM device may be improved. A ratio of W_{P}′ over W_{P} (W_{P}′/W_{P}) may range from about 0.75 to about 1 (0.75<W_{P}′/W_{P}<1), in some embodiments. The range is not trivial or arbitrary. If the ratio is not larger than about 0.75, the channel width for the transistors PU-1, PU-2 may be too small to provide sufficient current drive capability; if the ratio is larger than 1, the transistors R-PG won't have stronger current drive capability than the transistors PU-1, PU-2 to achieve the Vmin improvement. In some embodiments, the difference between the widths (W_{P}′−W_{P}) may range from about 2 nm to about 8 nm. In the depicted embodiment, the jogs of the active region 204 are all positioned on one side of the active region 204 that faces the adjacent active region 202. The opposite side of the active region 204, which faces the adjacent active region 204, is free of jogs. Each jog of the active region 204 is position between the gate structure of the transistor PU-2 and the gate structure of the transistor R-PG along the X-direction, such as in the middle point between the two gate structures.

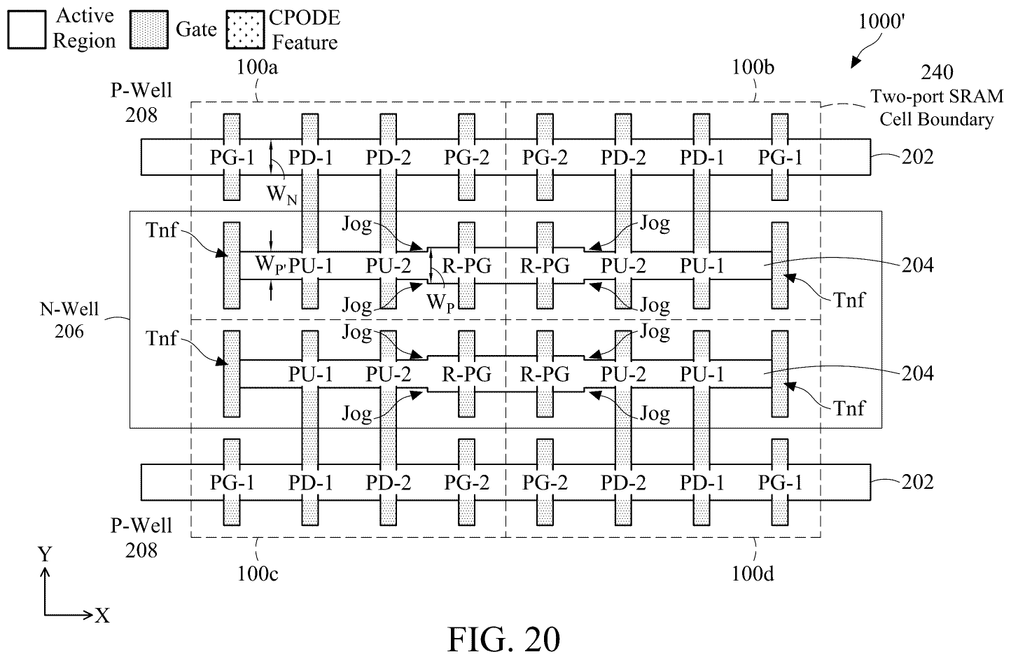

FIG. 20 illustrates an alternative layout 1000′ of the SRAM array, which is a variation of the layout 1000 in FIG. 19. Different from the layout 1000, in the alternative layout 1000′, the jogs of the active region 204 are positioned on both sides of the active region 204.

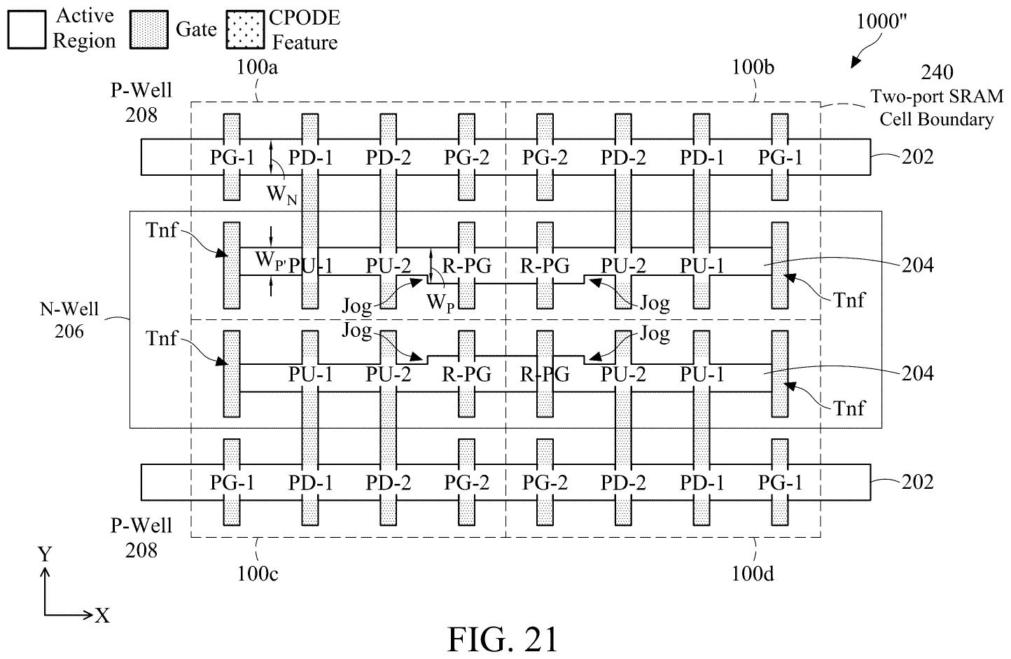

FIG. 21 illustrates an alternative layout 1000″ of the SRAM array, which is a variation of the layout 1000 in FIG. 19. Different from the layout 1000, in the alternative layout 1000″, the jogs of the active region 204 are all positioned on one side of the active region 204 that faces the adjacent active region 204. The opposite side of the active region 204, which faces the adjacent active region 202, is free of jogs. The choice of the layouts 1000, 1000′, and 1000″ mainly depends on the distance requirement between the adjacent same type and opposite type active regions, particularly when the design rules have set limitations on minimum distances between the adjacent same type and/or opposite type active regions.

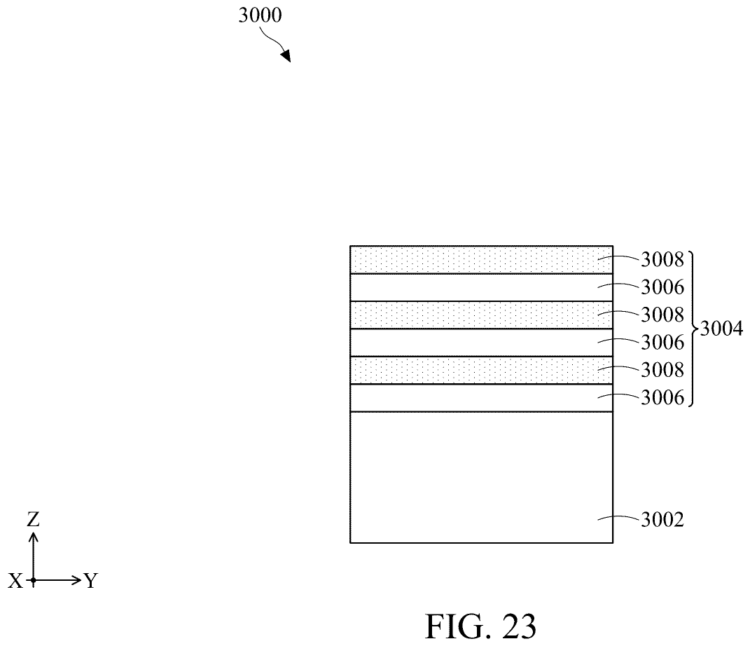

To support the fine tuning of SRAM device performance by introducing variable action region widths (e.g., W_{P} and W_{P}′ in FIGS. 12-21), the current drive capability of the transistors, particularly the p-type transistors formed on the p-type active regions, need to have performance margins (design headroom). In light of this requirement, the present disclosure implements a modified approach in GAA transistor manufacturing that improves the current drive capability of GAA transistors, and consequently, such an improvement allows active regions to be able to vary the widths without compromising transistors' current drive capability. The manufacturing flow will now be described in detail with reference to the following figures. In that regard, FIG. 22 is a flowchart illustrating a method 2000 of forming a semiconductor device from a work-in-progress (WIP) structure according to embodiments of the present disclosure. Method 2000 is merely an example and is not intended to limit the present disclosure to what is explicitly illustrated in method 2000. Additional steps can be provided before, during, and after method 2000, and some steps described can be replaced, eliminated, or moved around for additional embodiments of the method. Not all steps are described herein in detail for reasons of simplicity. Method 2000 is described below in conjunction with FIGS. 23-42, which are fragmentary cross-sectional views of a WIP structure 3000 at different stages of fabrication according to embodiments of method 2000 in FIG. 22. Because the WIP structure 3000 will be fabricated into a semiconductor device or a semiconductor structure, such as the IC device 10 (including the memory array containing the SRAM cells 100). The WIP structure 3000 may be referred to herein as a semiconductor device 3000 or a memory device 3000 as the context requires.

Referring to FIGS. 22 and 23, method 2000 includes a block 2002 where a stack 3004 of alternating semiconductor layers is formed over the WIP structure 3000. As shown in FIG. 23, the WIP structure 3000 includes a substrate 3002. The substrate 3002 may be implemented as the substrate 12 in the IC device 10 as depicted above. In some embodiments, the substrate 3002 may be a semiconductor substrate such as a silicon (Si) substrate. The substrate 3002 may include various doping configurations depending on design requirements as is known in the art. In embodiments where the semiconductor device is p-type, an n-type doping profile (i.e., an n-type well or n-well) may be formed on the substrate 3002. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 3002. In some implementations, the p-type dopant for forming the p-type well may include boron (B) or gallium (Ga). The suitable doping may include ion implantation of dopants and/or diffusion processes. The substrate 3002 may also include other semiconductors such as germanium (Ge), silicon carbide (SiC), silicon germanium (SiGe), germanium tin (GeSn), or diamond. Alternatively, the substrate 3002 may include a compound semiconductor and/or an alloy semiconductor. Further, the substrate 3002 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 3004 over the substrate 3002 includes channel layers 3008 of a first semiconductor composition interleaved by sacrificial layers 3006 of a second semiconductor composition. It can also be said that the sacrificial layers 3006 are interleaved by the channel layers 3008. The first and second semiconductor composition may be different. In some embodiments, the sacrificial layers 3006 include silicon germanium (SiGe) or germanium tin (GeSn) and the channel layers 3008 include silicon (Si). It is noted that three (3) layers of the sacrificial layers 3006 and three (3) layers of the channel layers 3008 are alternately arranged as illustrated in FIG. 10, which is for illustrative purposes only and not intended to be limiting beyond what is specifically recited in the claims. It can be appreciated that any number of epitaxial layers may be formed in the stack 3004. The number of layers depends on the desired number of channels members for the semiconductor device 3000. In some embodiments, the number of channel layers 3008 is between 2 and 10.

The sacrificial layers 3006 and channel layers 3008 in the stack 3004 may be deposited using a molecular beam epitaxy (MBE) process, a vapor phase deposition (VPE) process, and/or other suitable epitaxial growth processes. As stated above, in at least some examples, the sacrificial layers 3006 include an epitaxially grown silicon germanium (SiGe) layer and the channel layers 3008 include an epitaxially grown silicon (Si) layer. In some embodiments, the sacrificial layers 3006 and the channel layers 3008 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 3004.

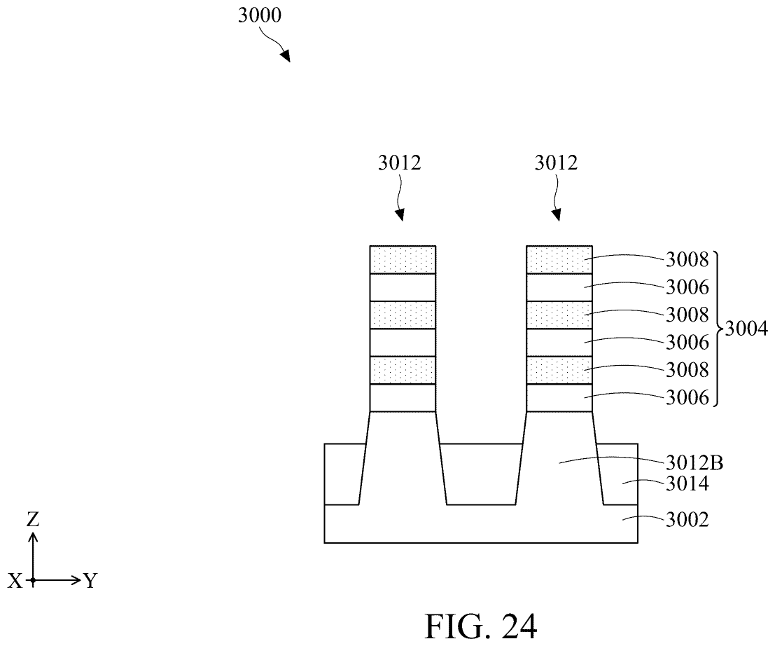

Referring to FIGS. 22 and 24, method 2000 includes a block 2004 where fin-shaped structures 3012 are formed from the stack 3004 and the substrate 3002. In some implementations, the two fin-shaped structures 3012 as depicted in FIG. 24 may be implemented as the two active regions 202 and 204 in the SRAM cell 100. To pattern the stack 3004, a hard mask layer may be deposited over the stack 3004 to form an etch mask. The hard mask layer may be a single layer or a multi-layer. For example, the hard mask layer may include a pad oxide layer and a pad nitride layer disposed over the pad oxide layer. The fin-shaped structure 3012 may be patterned from the stack 3004 and the substrate 3002 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 24, the etch process at block 2004 forms trenches extending vertically through the stack 3004 and a portion of the substrate 3002. The trenches define the fin-shaped structures 3012. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 3012 by etching the stack 3004 and a portion of the substrate 3002. As shown in FIG. 24, the fin-shaped structure 3012 that includes the sacrificial layers 3006 and the channel layers 3008 extends vertically along the Z-direction and lengthwise along the X-direction. Each of the fin-shaped structures 3012 includes a base fin structure 3012B patterned from the substrate 3002 and the patterned stack 3004 disposed directly over the base fin structure 3012B.

Still referring to FIGS. 22 and 24, method 2000 includes a block 2006 where an isolation feature 3014 is formed around a base fin structure 3012B of the fin-shaped structures 3012. The isolation feature 3014 may be implemented as the isolation feature 18 in the IC device 10 as depicted above. In some embodiments represented in FIG. 24, the isolation feature 3014 is disposed on sidewalls of the base fin structure 3012B. In some embodiments, the isolation feature 3014 may be formed in the trenches to isolate the fin-shaped structures 3012 from a neighboring fin-shaped structure. The isolation feature 3014 may also be referred to as a shallow trench isolation (STI) feature 3014. By way of example, in some embodiments, a dielectric layer is first deposited over the substrate 3002, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 3014 shown in FIG. 24. The fin-shaped structure 3012 rises above the STI feature 3014 after the recessing, while the base fin structure 3012B is embedded or buried in the STI feature 3014.

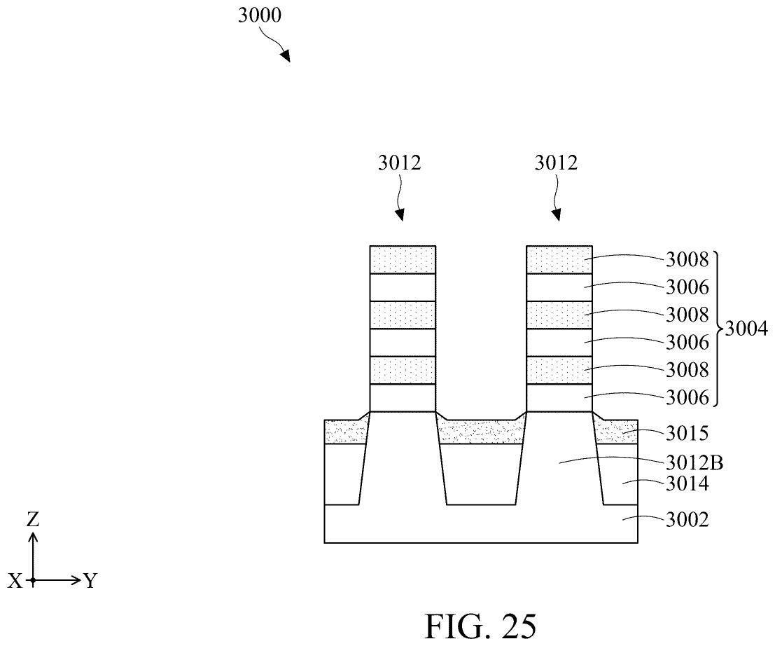

Referring to FIGS. 22 and 25, method 2000 includes a block 2008 where a hard mask layer 3015 is formed over the STI feature 3014 and around a top portion of the base fin structure 3012B. The hard mask layer 3015 may be implemented as the hard mask layer 50 as depicted in FIGS. 7B and 11. A composition of the hard mask layer 3015 is different from a composition of the STI feature 3014 to ensure that each one of them may be selectively etched without substantially damaging the other one. In some embodiments, the STI feature 3014 includes an oxide, and the hard mask layer 3015 includes a nitride (e.g., silicon nitride) or an oxynitride (e.g., silicon oxynitride). By way of example, in some embodiments, a nitride-containing material is first deposited over the STI feature 3014, filling the trenches with nitride. In various examples, the nitride-containing material may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the hard mask layer 3015. The fin-shaped structure 3012 rises above the hard mask layer 3015 after the recessing, while the base fin structure 3012B is embedded or buried in the combination of the STI feature 3014 and the hard mask layer 3015.

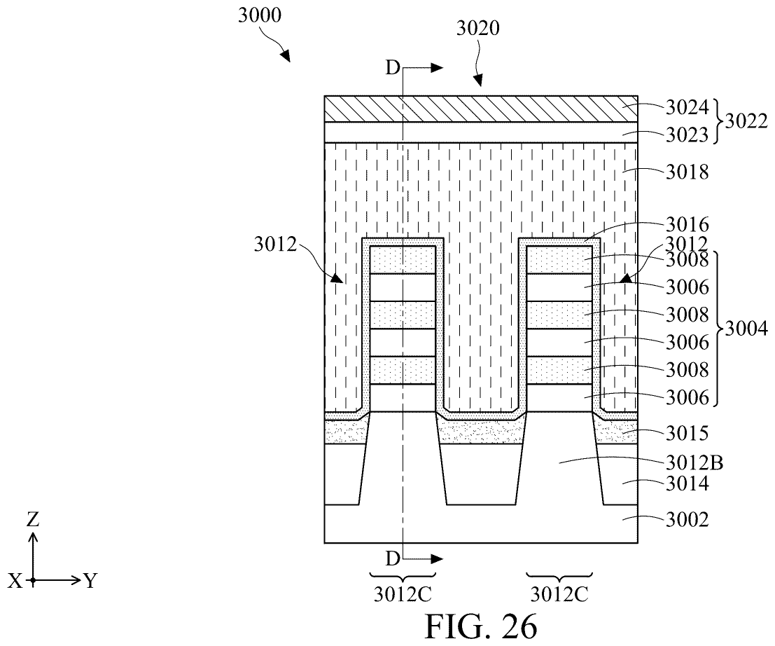

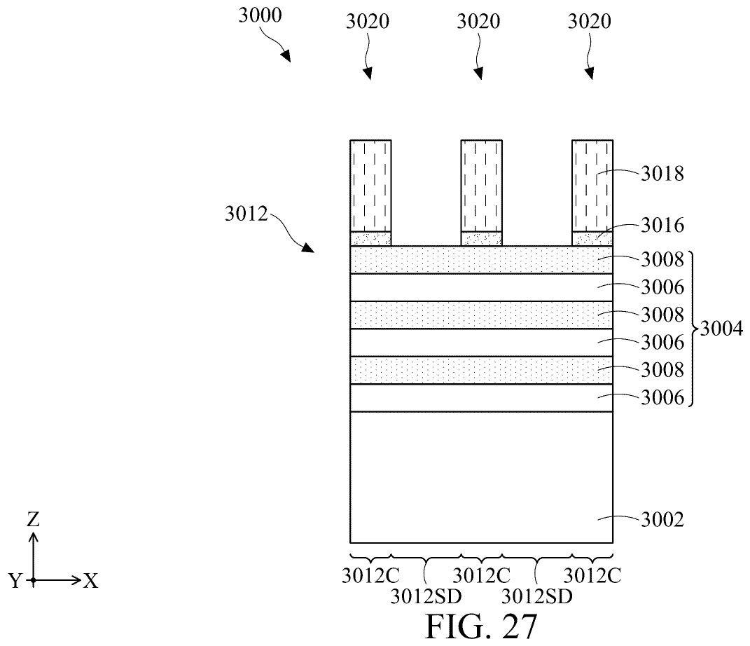

Referring to FIGS. 22 and 26-27, method 2000 includes a block 2010 where a dummy gate stack 3020 is formed over a channel region 3012C of the fin-shaped structure 3012. The dummy gate stack 3020 serves as a placeholder to undergo various processes and is to be removed and replaced by a functional gate structure. In some embodiments illustrated in FIG. 27, which is a cross-sectional view cut along the D-D line in FIG. 26, the dummy gate stack 3020 is formed over the fin-shaped structure 3012 and the fin-shaped structure 3012 may be divided into channel regions 3012C underlying the dummy gate stacks 3020 and source/drain regions 3012SD that do not underlie the dummy gate stacks 3020. The channel regions 3012C are adjacent to the source/drain regions 3012SD. As shown in FIG. 27, the channel region 3012C is disposed between two source/drain regions 3012SD along the X direction.

The formation of the dummy gate stack 3020 may include deposition of layers in the dummy gate stack 3020 and patterning of these layers. Referring to FIG. 26, a dummy dielectric layer 3016, a dummy electrode layer 3018, and a gate-top hard mask layer 3022 may be blanketly deposited over the WIP structure 3000. The dummy dielectric layer 3016 may be formed on the fin-shaped structure 3012 using a chemical vapor deposition (CVD) process, an ALD process, an oxygen plasma oxidation process, or other suitable processes. In some instances, the dummy dielectric layer 3016 may include silicon oxide. Thereafter, the dummy electrode layer 3018 may be deposited over the dummy dielectric layer 3016 using a CVD process, an ALD process, or other suitable processes. In some instances, the dummy electrode layer 3018 may include polysilicon. For patterning purposes, the gate-top hard mask layer 3022 may be deposited on the dummy electrode layer 3018 using a CVD process, an ALD process, or other suitable processes. The gate-top hard mask layer 3022, the dummy electrode layer 3018, and the dummy dielectric layer 3016 may then be patterned to form the dummy gate stack 3020, as shown in FIG. 26. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 3022, the dummy electrode layer 3018, and the dummy dielectric layer 3016. In some embodiments, the etching process may include dry etching (e.g., RIE etching), wet etching, and/or other etching methods. In some embodiments, the gate-top hard mask layer 3022 may include a silicon oxide layer 3023 and a silicon nitride layer 3024 over the silicon oxide layer 3023. As shown in FIG. 27, the dummy gate stack 3020 is patterned such that it is only disposed over the channel region 3012C, not disposed over the source/drain region 3012SD.

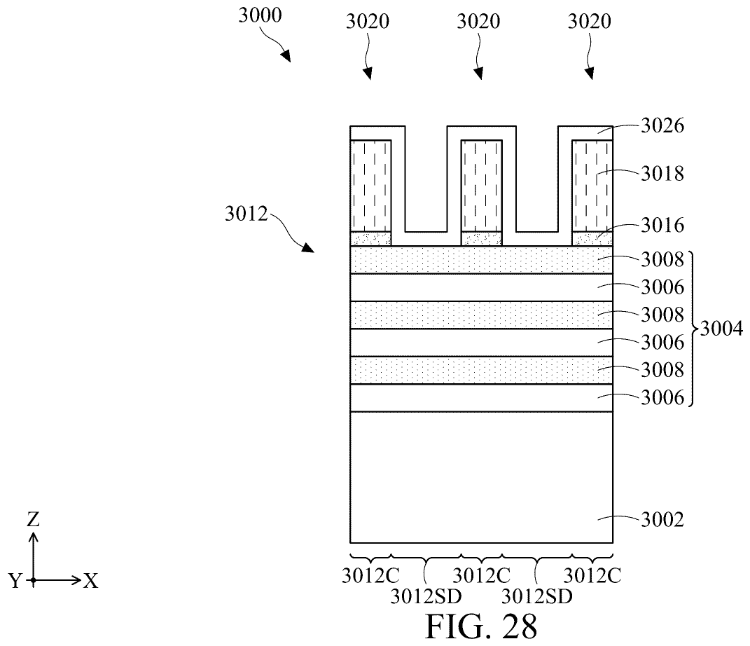

Referring to FIGS. 22 and 28, method 2000 includes a block 2012 where a gate spacer layer 3026 is deposited over the WIP structure 3000, including over the dummy gate stack 3020. In some embodiments, the gate spacer layer 3026 is deposited conformally over the WIP structure 3000, including over top surfaces and sidewalls of the dummy gate stack 3020. The term “conformally” may be used herein for ease of description of a layer having substantially uniform thickness over various regions. The gate spacer layer 3026 may be a single layer or a multi-layer. The at least one layer in the gate spacer layer 3026 may include silicon carbonitride, silicon oxycarbide, silicon oxycarbonitride, or silicon nitride. The gate spacer layer 3026 may be deposited over the dummy gate stack 3020 using processes such as, a CVD process, a subatmospheric CVD (SACVD) process, an ALD process, or other suitable process.

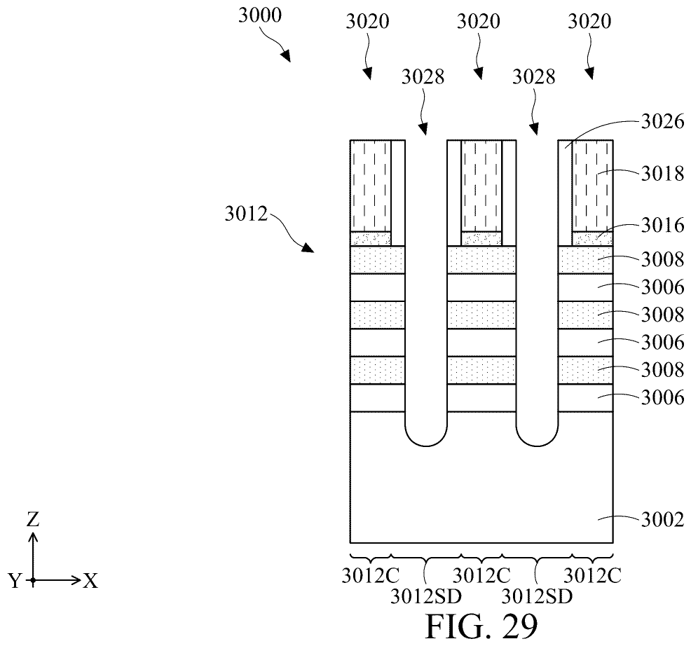

Referring to FIGS. 22 and 29, method 2000 includes a block 2014 where source/drain regions 3012SD of the fin-shaped structure 3012 are anisotropically recessed to form source/drain trenches 3028. The anisotropic etch may include a dry etch or a suitable etch process that etches the source/drain regions 3012SD and a portion of the substrate 3002. The resulting source/drain trench 3028 extends vertically through the depth of the stack 3004 and partially into the substrate 3002. An example dry etch process for block 2014 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 29, the source/drain regions 3012SD of the fin-shaped structure 3012 are recessed to expose sidewalls of the sacrificial layers 3006 and the channel layers 3008. Because the source/drain trenches 3028 extend below the stack 3004 into the substrate 3002, the source/drain trenches 3028 include bottom surfaces and lower sidewalls defined in the substrate 3002.

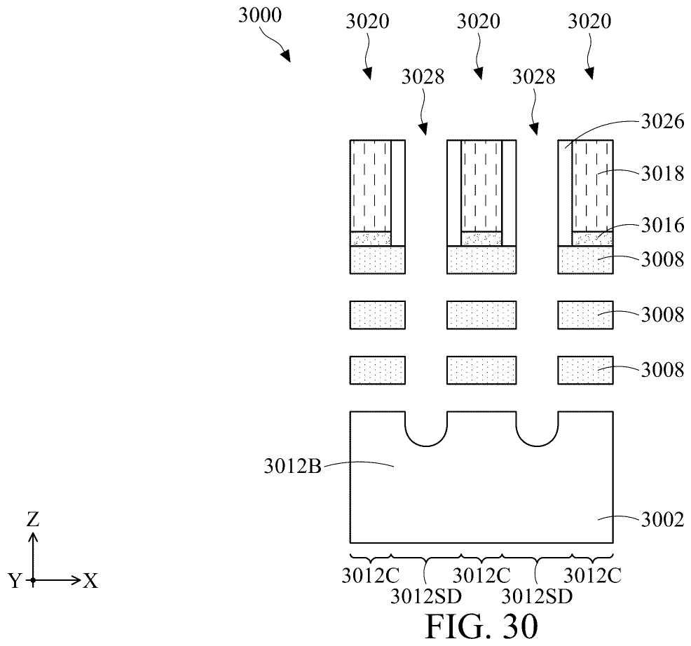

Referring to FIGS. 22 and 30, method 2000 includes a block 2016 where the plurality of channel layers 3008 in the channel regions are released as channel members 3008. The channel members 3008 may correspond to the nanostructures 26 in the IC device 10. Depending on the design, the channel members 3008 may take form of nanowires, nanosheets, or other nanostructures. After the formation of the source/drain trench 3028, the sacrificial layers 3006 interleaving the channel layers 3008 in the channel region 3012C are selectively removed. The selective removal of the sacrificial layers 3006 releases the channel layers 3008 to form channel members 3008 shown in FIG. 30. The selective removal of the sacrificial layers 3006 forms spaces between and around adjacent channel members 3008. The selective removal of the sacrificial layers 3006 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

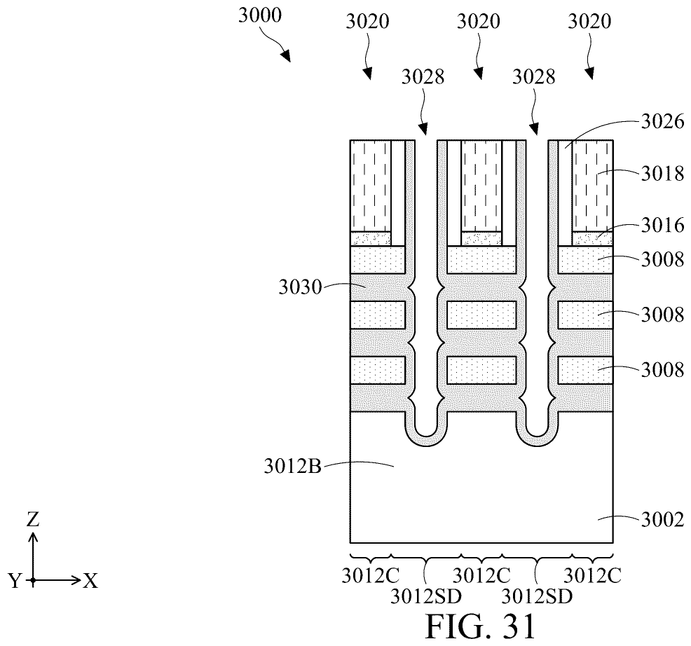

Referring to FIGS. 22 and 31, method 2000 includes a block 2018 where a dielectric dummy layer 3030 is deposited around the channel members 3008 and over the source/drain trenches 3028. The dummy layer 3030 may include silicon oxide and may be deposited using plasma enhanced chemical vapor deposition (PECVD) or ALD. The dummy layer 3030 fills the space among the channel members 3008 and covers end sidewalls of the channel members 3008. Additionally, the dummy layer 3030 is in direct contact with a sidewall of the gate spacer layer 3026 and a top surface of the substrate 3002.

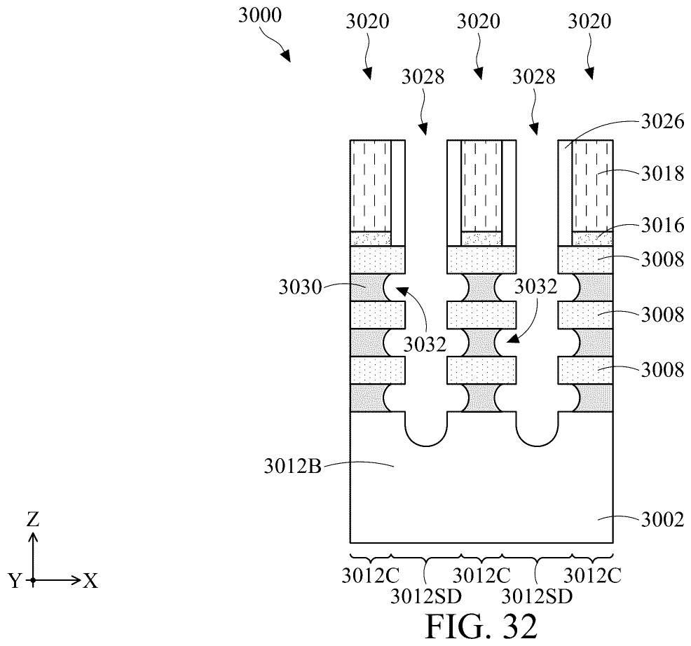

Referring to FIGS. 22 and 32, method 2000 includes a block 2020 where inner spacer recesses 3032 are formed. The dummy layers 3030 are selectively and partially recessed to form inner spacer recesses 3032 while the gate spacer layer 3026, the dummy gate stack 3020, the exposed portion of the substrate 3002, and the channel layers 3008 are substantially unetched. In an embodiment where the channel layers 3008 consist essentially of silicon (Si) and the dummy layers 3030 are formed of silicon oxide, the selective recess of the dummy layer 3030 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

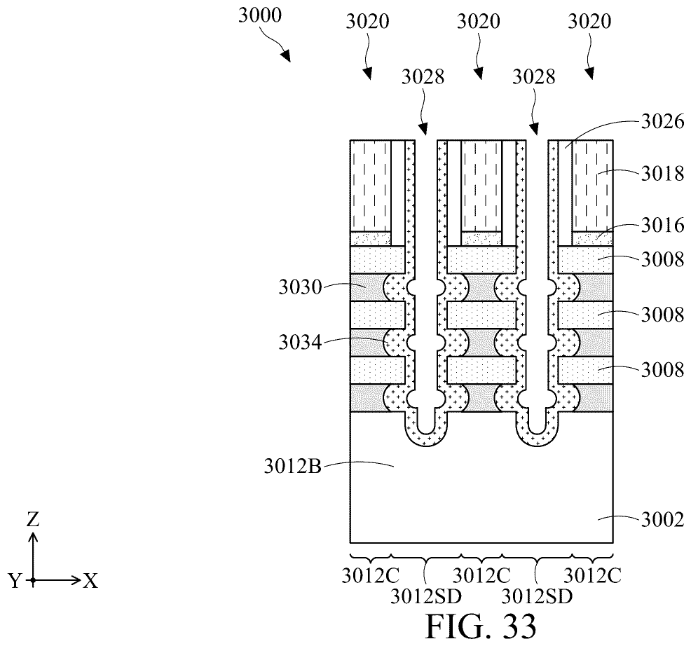

Referring to FIGS. 22 and 33, method 2000 includes a block 2022 where an inner spacer layer 3034 is deposited over the inner spacer recesses 3032. A composition of the inner spacer layer 3034 is different from a composition of the dielectric dummy layer 3030 to ensure that each one of them may be selectively etched without substantially damaging the other one. In some embodiments, the inner spacer layer 3034 may include silicon carbonitride (SiCN), silicon oxycarbonitride (SiOCN), silicon nitride (SiN), silicon oxycarbide (SiOC), or silicon oxynitride (SiON). In some implementations, the inner spacer layer 3034 may be deposited using CVD or ALD.

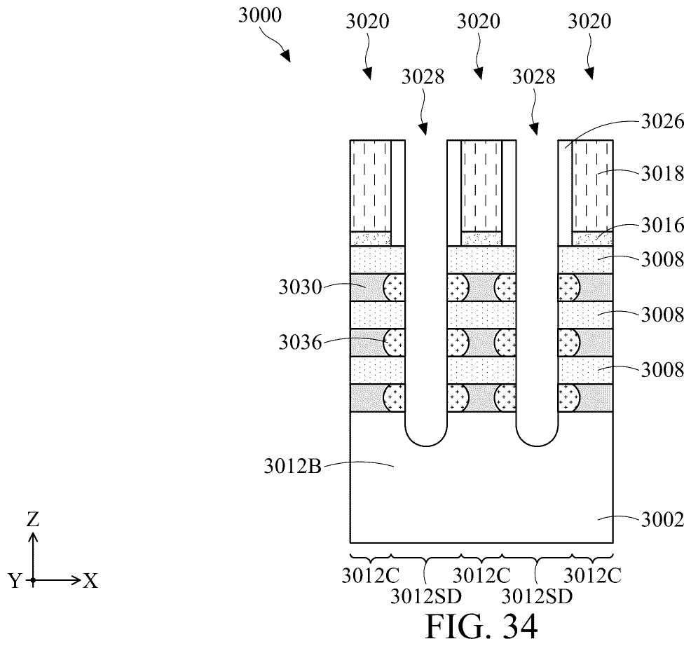

Referring to FIGS. 22 and 34, method 2000 includes a block 2024 where the inner spacer layer 3034 is etched back to form inner spacers 3036 over the inner spacer recesses 3032. In some embodiments, the etching back at block 2024 may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In the depicted embodiment, the inner spacers 3036 laterally extend to a position directly under the dummy gate stack 3020. Alternatively, the inner spacers 3036 may substantially remain under the gate spacer layer 3026 without extending to a position directly under the dummy gate stack 3020.

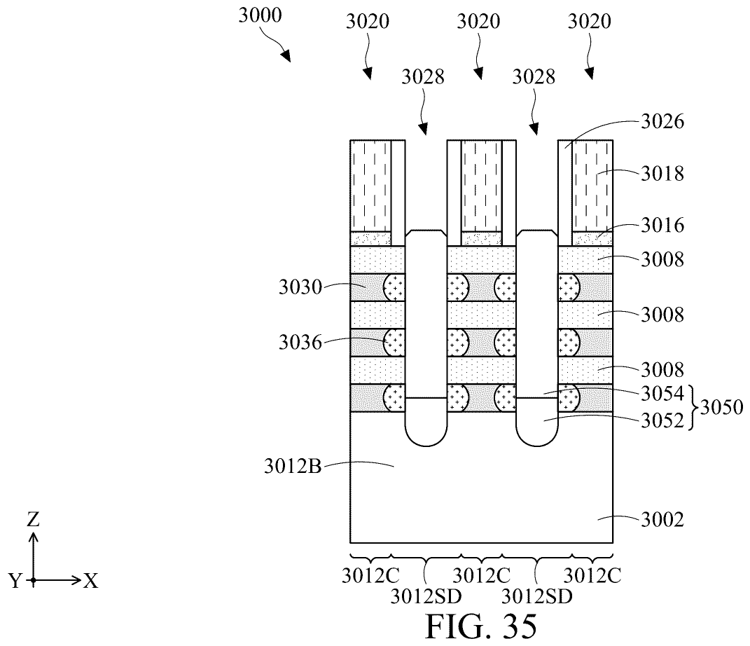

Referring to FIGS. 22 and 35, method 2000 includes a block 2028 where a source/drain feature 3050 is formed over the source/drain region 3012SD. The source/drain feature 3050 may be implemented as the source/drain features 16 in the IC device 10. While not explicitly shown, before any of the epitaxial layers are formed, method 2000 may include a cleaning process to clean surfaces of the WIP structure 3000. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

In some embodiments, a source/drain feature 3050 includes a bottom epitaxial feature 3052 and a main epitaxial feature 3054 over the bottom epitaxial feature 3052. The source/drain feature 3050 may be n-type or p-type. When the source/drain feature 3050 is n-type, the bottom epitaxial feature 3052 may include undoped silicon (Si) or undoped silicon germanium (SiGe) and the main epitaxial feature 3054 may include silicon (Si) and an n-type dopant, such as phosphorus (P), arsenic (As), antimony (Sb), or a combination thereof. When the source/drain feature 3050 is p-type, the bottom epitaxial feature 3052 may include undoped silicon (Si) or undoped silicon germanium (SiGe) and the main epitaxial feature 3054 may include silicon germanium (SiGe) and a p-type dopant, such as boron (B), boron difluoride (BF₂), or a combination thereof. As used herein, the undoped semiconductor material is regarded as undoped when it is not intentionally doped. In some alternative embodiments, the bottom epitaxial feature 3052 may include a counter dopant to reduce leakage into the bulk substrate 3002. For example, the bottom epitaxial feature 3052 in the n-type source/drain feature 3050 may include a p-type dopant, such as boron (B). For another example, the bottom epitaxial feature 3052 in the p-type source/drain feature 3050 may include an n-type dopant, such as phosphorus (P), arsenic (As), or antimony (Sb). The source/drain feature 3050 may be formed using vapor-phase epitaxy (VPE), ultra-high vacuum CVD (UHV-CVD), or molecular beam epitaxy (MBE). Doping of the source/drain features 3050 may be achieved with in-situ doping.

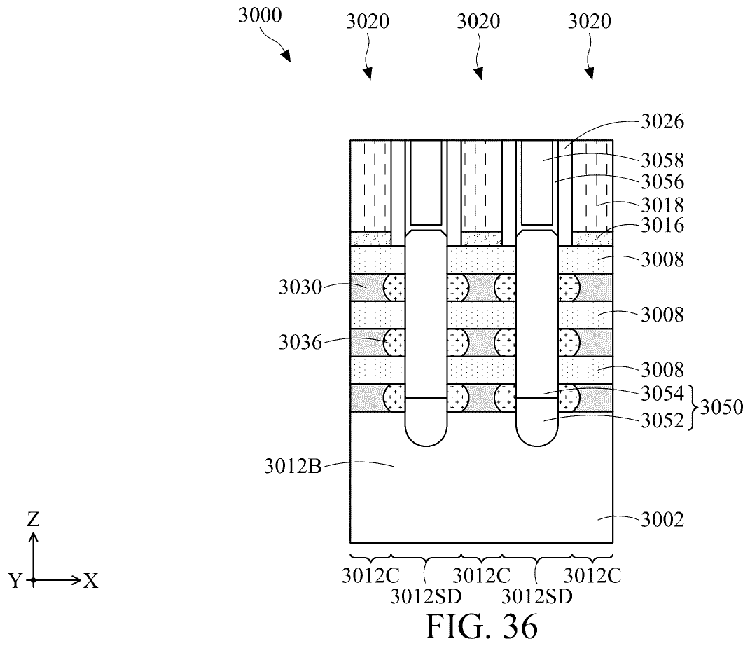

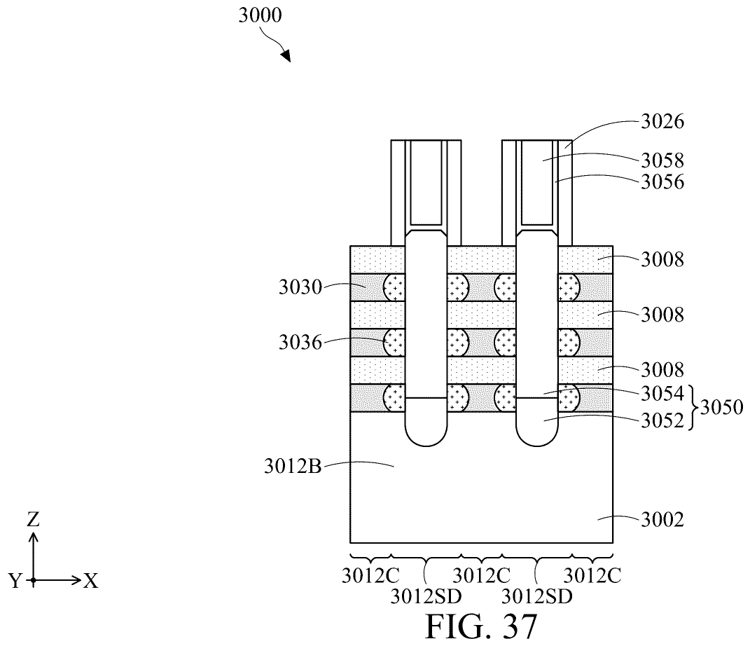

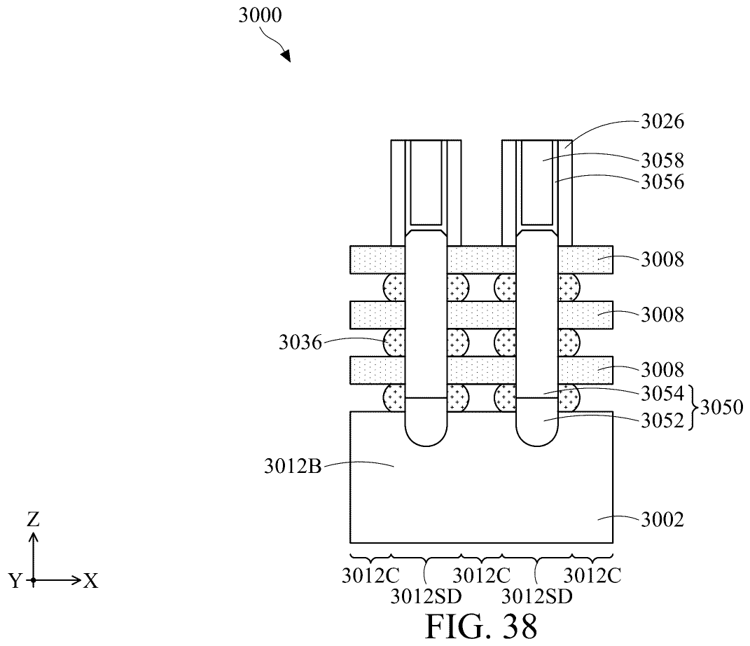

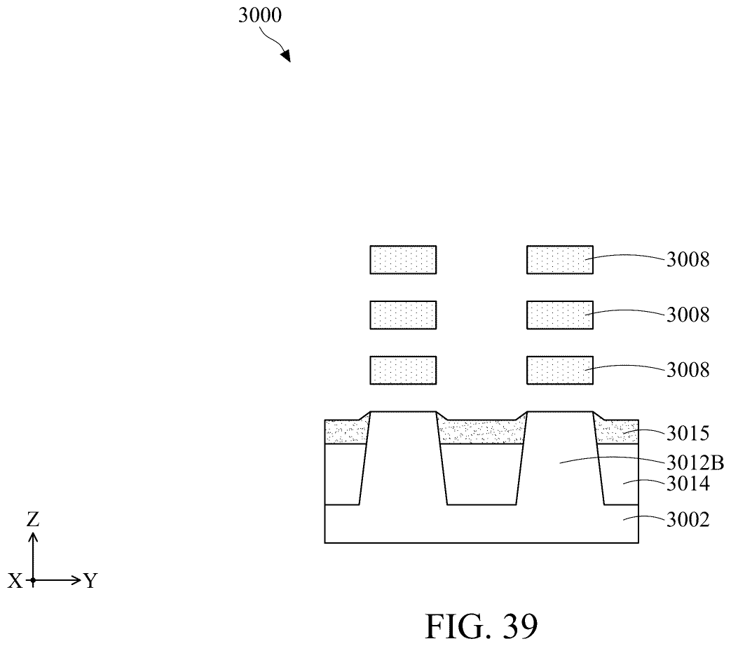

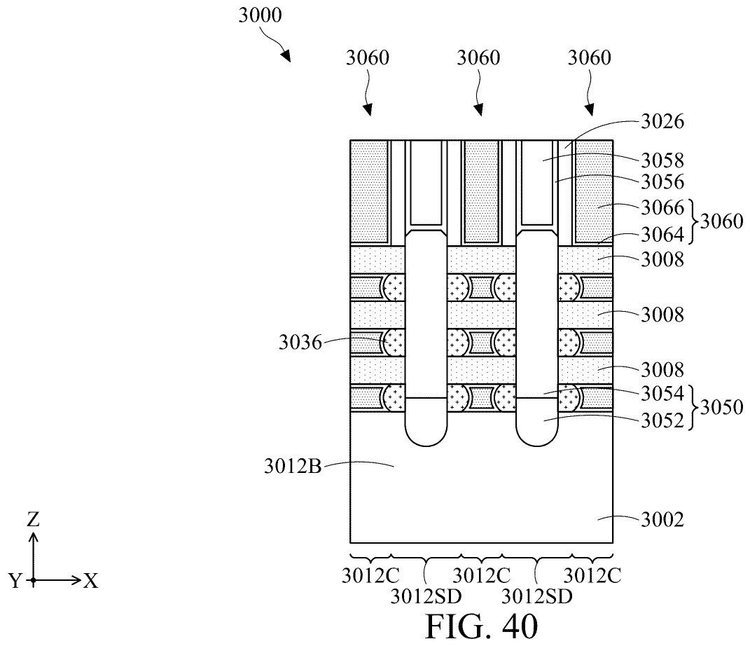

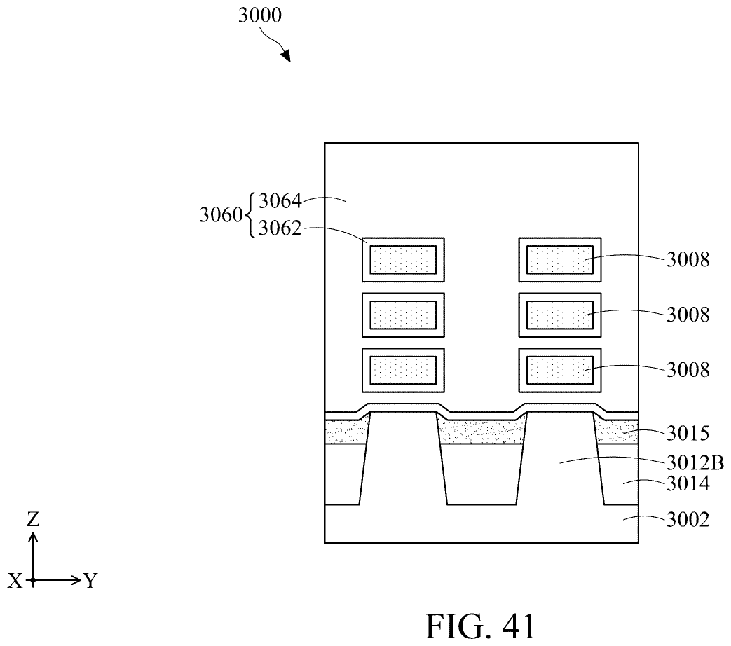

Referring to FIGS. 22 and 36-41, method 2000 includes a block 2030 where the dummy gate stack 3020 and the dummy layer 3030 are replaced with a gate structure 3060 (also referred to as metal gate structure 3060). Operations at block 2030 may include deposition of a contact etch stop layer (CESL) 3056 over the source/drain features 3050 (shown in FIG. 36), deposition of an interlayer dielectric layer 3058 over the CESL 3056 (shown in FIG. 36), removal of the dummy gate stack 3020 (shown in FIG. 37), removal of the dummy layer 3030 (shown in FIGS. 38 and 39), and deposition of the gate structure 3060 to wrap around each of the channel members 3008 (shown in FIGS. 40 and 41). Referring to FIG. 36, the CESL 3056 is deposited over the WIP structure 3000, including over the source/drain feature 3050. The CESL 3056 may include silicon nitride or aluminum nitride. In some implementations, the CESL 3056 may be deposited using CVD or atomic layer deposition (ALD). The ILD layer 3058 is then deposited over the CESL 3056. In some embodiments, the ILD layer 3058 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 3058 may be deposited using CVD, flowable CVD (FCVD), spin-on coating, or a suitable deposition technique. After the deposition of the ILD layer 3058, the WIP structure 3000 may be planarized by a planarization process to expose the dummy gate stack 3020. For example, the planarization process may include a chemical mechanical planarization (CMP) process. Exposure of the dummy gate stack 3020 allows the removal of the dummy gate stack 3020. The removal of the dummy gate stack 3020 may include one or more etching processes that are selective to the material of the dummy gate stack 3020. For example, the removal of the dummy gate stack 3020 may be performed using as a selective wet etch, a selective dry etch, or a combination thereof that is selective to the dummy gate stack 3020.

After the removal of the dummy gate stack 3020, the dummy layer 3030 in the channel region 3012C is exposed. A separate etch process may be performed to selectively remove the dummy layer 3030 in the channel region 3012C. For example, a selective wet etch process or a selective dry etch process may be performed to remove the dummy layer 3030. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. The selective etch of the dummy layer 3030 etches the channel members 3008 at a much smaller rate, such that the integrity of the channel members 3008 is preserved. The hard mask layer 3015 also protects the STI feature 3014 from the etching loss during the removal of the dummy layer 3030. The presence of the hard mask layer 3015 is one of the distinguishing characteristics of the presented modified approach of forming the GAA transistors. After the selective removal of the dummy layer 3030, the channel members 3008 in the channel region 3012C are once again exposed as shown in FIGS. 38 and 39.

After the release of the channel members 3008, the gate structure 3060 is formed to wrap around each of the channel members 3008 as shown in FIGS. 40 and 41. The gate structure 3060 includes a gate dielectric layer 3062 interfacing the channel members 3008 and the substrate 3002 in the channel region 3012C and a gate electrode layer 764 over the gate dielectric layer 3062.

The gate dielectric layer 3062 may include an interfacial layer and a high-k dielectric layer over the interfacial layer The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include a high-k dielectric material, such as hafnium oxide. Alternatively, the high-k dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The high-k dielectric layer may be formed by ALD, physical vapor deposition (PVD), CVD, oxidation, and/or other suitable methods. The gate dielectric layer 3062 also covers sidewalls of the inner spacers 736.

The gate electrode layer 764 of the gate structure 3060 may include a multi-layer structure, such as various combinations of a metal layer with a selected work function to enhance the device performance (referred to as work function metal (WFM) layer), a liner layer, a wetting layer, an adhesion layer, a metal alloy or a metal silicide. By way of example, the gate electrode layer 766 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 764 may be formed by ALD, PVD, CVD, e-beam evaporation, or other suitable process. In various embodiments, a CMP process may be performed to remove excessive metal, thereby providing a substantially planar top surface of the gate structure 3060. The gate structure 3060 includes portions that interpose between channel members 3008 in the channel region 3012C. In some embodiments, the gate structure 3060 may be an n-type gate structure or a p-type gate structure. The n-type gate structure includes an n-type work function metal layer disposed closer to the channel members 3008. The p-type gate structure includes a p-type work function metal layer disposed closer to the channel members 3008.

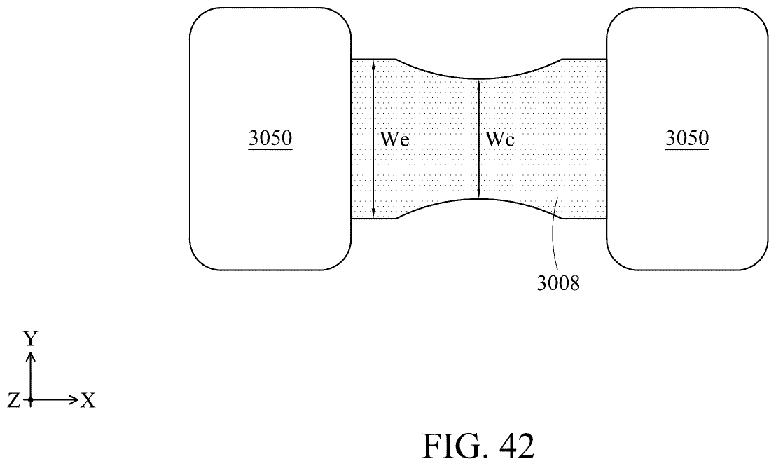

FIG. 42 shows a plane view of one of the channel members 3008 at the conclusion of the gate replacement process, in some embodiments. The channel member 3008, as a nanostructure (e.g., nanosheet, nanowire), connects the opposing source/drain features 3050 and provides the channel region for the respective transistor. In some implementations of a gate replacement process, a dummy gate stack is initially formed as a placeholder and subsequently replaced with a functional gate structure. Sacrificial materials among nanostructures of the GAA transistor are removed after epitaxial source/drain features are formed. Ideally, due to the different material compositions, a large etch selectivity between the sacrificial materials (e.g., SiGe) and the nanostructures (e.g., Si) should safeguard the nanostructures from etching loss during the removal of sacrificial materials. However, atoms other than silicon (e.g., Ge) in the sacrificial materials may diffuse into the nanostructures as impurities during annealing processes, such as those used in forming the epitaxial source/drain features. This diffusion of impurities lowers the etching selectivity, potentially causing etching loss in the nanostructures during sacrificial material removal. For example, nanostructure edges may become non-flat with a curvature profile due to extra etching loss. Consequently, the width of the channel member 3008 measured at the ends (denoted as We) and at the center (denoted as Wc) would differ. This deviation may range from about 5% to about 50%, or expressed as a ratio, We/Wc may range from about 1.05 to about 1.5 (1.05<We/Wc<1.5). Such a significant curvature profile at the nanostructure edges may cause gate structure profile variation, resulting in non-uniform device performance. In contrast, the present disclosure replaces the sacrificial materials with a dielectric dummy layer 3030 prior to subsequent annealing processes, thereby impeding impurity diffusion. Consequently, the channel members 3008 are released by removing the dielectric dummy layer 3030. The etching selectivity between the dielectric dummy layer 3030 and the channel members 3008 is significantly larger than that between the sacrificial layer 3006 and the channel members 3008. By design, the etch selectivity of the dielectric dummy layer 3030 over the channel members 3008 may exceed 10000:1, ensuring the channel members 3008 remain substantially intact. As a result, the width deviation between ends and center is limited to below 5%, or expressed as a ratio, We/Wc may range from about 1 to about 1.05 (1<We/Wc<1.05). Consequently, the current drive capability is improved by 20% to 50% in some embodiments. This performance boost allows design headroom for varying the active region widths as discussed above.

In one exemplary aspect, the present disclosure is directed to a memory cell. The memory cell includes first and second active regions. Each of the first and second active regions extends lengthwise in a first direction. The memory cell also includes first, second, third, and fourth gate structures arranged in order from first to fourth along the first direction. Each of the first, second, third, and fourth gate structures extends lengthwise in a second direction that is perpendicular to the first direction. The first, second, third, and fourth gate structures are configured to engage the first active region in forming first, second, third, and fourth transistors of a write-port of the memory cell, respectively, and the second and third gate structures are configured to further engage the second active region in forming fifth and sixth transistors of the write-port of the memory cell. The memory cell also includes a fifth gate structure extending lengthwise in the second direction. The fifth gate structure is configured to engage the second active region in forming a seventh transistor of a read-port of the memory cell. The second active region has a first segment providing a channel region for the seventh transistor and a second segment providing channel regions for the fifth and sixth transistors. The first segment has a first width, and the second segment has a second width that is different from the first width. In some embodiments, the first width is smaller than the second width. In some embodiments, a ratio of the first width over the second width ranges from about 0.75 to about 1. In some embodiments, the first width is larger than the second width. In some embodiments, a ratio of the first width over the second width ranges from about 1 to about 1.25. In some embodiments, the first active region has a third width that equals either the first width or the second width. In some embodiments, the first, second, third, and fourth transistors are n-type transistors, and the fifth, sixth, and seventh transistors are p-type transistors. In some embodiments, the memory cell further includes an isolation structure disposed between the first active region and the second active region, and a hard mask layer disposed on the isolation structure. The hard mask layer and the isolation structure include different material compositions. In some embodiments, the second active region includes a first edge facing the first active region and a second edge facing away from the first active region, the second active region includes a jog located at a transition between the first segment and the second segment, the jog is located on the first edge, and the second edge is flat. In some embodiments, the second active region includes a first edge facing the first active region and a second edge facing away from the first active region, the second active region includes first and second jogs located at a transition between the first segment and the second segment, the first jog is located on the first edge, and the second jog is located on the second edge.

In another exemplary aspect, the present disclosure is directed to a semiconductor device. The semiconductor device includes a write-port of a memory cell, wherein the write-port includes at least a pull-up (PU) transistor, a pull-down (PD) transistor, and a pass-gate (PG) transistor, and a read-port of the memory cell, wherein the read-port includes a PG transistor. The PG transistor in the write-port is an n-type transistor. The PG transistor in the read-port is a p-type transistor. A channel region of the PD transistor in the write-port and a channel region of the PG transistor in the write-port are disposed on a first active region. A channel region of the PU transistor in the write-port and a channel region of the PG transistor in the read-port are disposed on a second active region extending parallel to the first active region. The second active region has a variable width. In some embodiments, the first active region has a constant width. In some embodiments, the second active region has a first segment corresponding to the channel region of the PG transistor in the read-port and a second segment corresponding to the channel region of the PU transistor in the write-port. The first segment is narrower than the second segment. In some embodiments, a ratio of widths of the first segment and the second segment ranges from about 0.75 to about 1. In some embodiments, the second active region has a first segment corresponding to the channel region of the PG transistor in the read-port and a second segment corresponding to the channel region of the PU transistor in the write-port, the first segment is wider than the second segment. In some embodiments, a ratio of widths of the first segment and the second segment ranges from about 1 to about 1.25.

In yet another exemplary aspect, the present disclosure is directed to a memory device. The memory device includes a first pass-gate (PG) transistor, a second PG transistor, a first pull-down (PD) transistor, and a second PD transistor sharing a first active region extending in a first direction, a first pull-up (PU) transistor, a second PU transistor, and a read-port pass-gate (R-PG) transistor sharing a second active region extending in the first direction, and an isolation feature abutting a gate structure of the first PG transistor and extending lengthwise in a second direction perpendicular to the first direction. The second active region is divided by the isolation feature into a first segment and a second segment, and the first segment and the second segment have different widths. In some embodiments, the second segment provides channel regions for the first PU transistor, the second PU transistor, and the R-PG transistor. In some embodiments, the second segment is wider than the first segment. In some embodiments, edges of the first and second segments facing away from the first active region are aligned, and opposing edges of the first and second segments facing the first active region are misaligned.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
first and second active regions, wherein each of the first and second active regions extends lengthwise in a first direction;
first, second, third, and fourth gate structures arranged in order from first to fourth along the first direction, wherein each of the first, second, third, and fourth gate structures extends lengthwise in a second direction that is perpendicular to the first direction, wherein the first, second, third, and fourth gate structures are configured to engage the first active region in forming first, second, third, and fourth transistors of a write-port of the memory cell, respectively, and wherein the second and third gate structures are configured to further engage the second active region in forming fifth and sixth transistors of the write-port of the memory cell; and
a fifth gate structure extending lengthwise in the second direction, wherein the fifth gate structure is configured to engage the second active region in forming a seventh transistor of a read-port of the memory cell,
wherein the second active region has a first segment providing a channel region for the seventh transistor and a second segment providing channel regions for the fifth and sixth transistors, the first segment has a first width, and the second segment has a second width that is different from the first width.

2. The memory cell of claim 1, wherein the first width is smaller than the second width.

3. The memory cell of claim 2, wherein a ratio of the first width over the second width ranges from about 0.75 to about 1.

4. The memory cell of claim 1, wherein the first width is larger than the second width.

5. The memory cell of claim 4, wherein a ratio of the first width over the second width ranges from about 1 to about 1.25.

6. The memory cell of claim 1, wherein the first active region has a third width that equals either the first width or the second width.

7. The memory cell of claim 1, wherein the first, second, third, and fourth transistors are n-type transistors, and the fifth, sixth, and seventh transistors are p-type transistors.

8. The memory cell of claim 1, further comprising:
an isolation structure disposed between the first active region and the second active region; and
a hard mask layer disposed on the isolation structure, wherein the hard mask layer and the isolation structure include different material compositions.

9. The memory cell of claim 1, wherein the second active region includes a first edge facing the first active region and a second edge facing away from the first active region, the second active region includes a jog located at a transition between the first segment and the second segment, the jog is located on the first edge, and the second edge is flat.

10. The memory cell of claim 1, wherein the second active region includes a first edge facing the first active region and a second edge facing away from the first active region, the second active region includes first and second jogs located at a transition between the first segment and the second segment, the first jog is located on the first edge, and the second jog is located on the second edge.

11. A semiconductor device, comprising:
a write-port of a memory cell, wherein the write-port includes at least a pull-up (PU) transistor, a pull-down (PD) transistor, and a pass-gate (PG) transistor; and
a read-port of the memory cell, wherein the read-port includes a PG transistor,
wherein:
the PG transistor in the write-port is an n-type transistor,
the PG transistor in the read-port is a p-type transistor,
a channel region of the PD transistor in the write-port and a channel region of the PG transistor in the write-port are disposed on a first active region,
a channel region of the PU transistor in the write-port and a channel region of the PG transistor in the read-port are disposed on a second active region extending parallel to the first active region, and
the second active region has a variable width.

12. The semiconductor device of claim 11, wherein the first active region has a constant width.

13. The semiconductor device of claim 11, wherein the second active region has a first segment corresponding to the channel region of the PG transistor in the read-port and a second segment corresponding to the channel region of the PU transistor in the write-port, the first segment is narrower than the second segment.

14. The semiconductor device of claim 13, wherein a ratio of widths of the first segment and the second segment ranges from about 0.75 to about 1.

15. The semiconductor device of claim 11, wherein the second active region has a first segment corresponding to the channel region of the PG transistor in the read-port and a second segment corresponding to the channel region of the PU transistor in the write-port, the first segment is wider than the second segment.

16. The semiconductor device of claim 15, wherein a ratio of widths of the first segment and the second segment ranges from about 1 to about 1.25.

17. A memory device, comprising:
a first pass-gate (PG) transistor, a second PG transistor, a first pull-down (PD) transistor, and a second PD transistor sharing a first active region extending in a first direction;
a first pull-up (PU) transistor, a second PU transistor, and a read-port pass-gate (R-PG) transistor sharing a second active region extending in the first direction; and
an isolation feature abutting a gate structure of the first PG transistor and extending lengthwise in a second direction perpendicular to the first direction,
wherein the second active region is divided by the isolation feature into a first segment and a second segment, and wherein the first segment and the second segment have different widths.

18. The memory device of claim 17, wherein the second segment provides channel regions for the first PU transistor, the second PU transistor, and the R-PG transistor.

19. The memory device of claim 18, wherein the second segment is wider than the first segment.

20. The memory device of claim 17, wherein edges of the first and second segments facing away from the first active region are aligned, and opposing edges of the first and second segments facing the first active region are misaligned.
